(19) United States
(12) Patent Application Publication
(10) Pub. No.: US 2025/0227912 A1
(43) Pub. Date: Jul. 10, 2025

(54) SEMICONDUCTOR MEMORY DEVICE

(71) Applicant: SAMSUNG ELECTRONICS CO., LTD., Suwon-si (KR)

(72) Inventors: Seong Min Choo, Suwon-si (KR); Mun Jun Kim, Suwon-si (KR); Jun-Won Lee, Suwon-si (KR); Youn-Seok Choi, Suwon-si (KR); Ik Soo Kim, Suwon-si (KR)

(21) Appl. No.: 18/814,193

(22) Filed: Aug. 23, 2024

(30) Foreign Application Priority Data
Jan. 4, 2024 (KR) 10-2024-0001278

(51) Int. Cl. H10B 12/00

(52) U.S. Cl. CPC H10B 12/315; H10B 12/033

(57) ABSTRACT

A semiconductor memory device includes a conductive pattern disposed on a substrate and a lower electrode connected to the conductive pattern and extending in a first direction. The lower electrode includes a lower pattern and an upper pattern. The lower electrode is disposed between the upper pattern and the conductive pattern. The device further includes a capacitor dielectric film disposed on the lower electrode and an upper electrode disposed on the capacitor dielectric film. The lower pattern includes a lower inner interface extending in the first direction, wherein the upper pattern is free of an inner interface extending in the first direction.

### CROSS-REFERENCE TO RELATED APPLICATION

This application claims priority from Korean Patent Application No. 10-2024-0001278 filed on Jan. 4, 2024 in the Korean Intellectual Property Office, the contents of which in its entirety are herein incorporated by reference.

### BACKGROUND

Recently, as semiconductor devices have become larger in capacity and more highly integrated, a design rule thereof is continuously decreasing. This trend is also occurring in DRAM as one of memory semiconductor devices. In order for a DRAM device to operate, each cell requires a certain level of capacitance.

An increase in the capacitance increases an amount of charge stored in the capacitor, thereby improving refresh characteristics of the semiconductor device. The improved refresh characteristics of the semiconductor device may improve a yield of the semiconductor device.

To increase the capacitance, research is being done on using a dielectric film with a high dielectric constant in the capacitor or increasing a contact area between a lower electrode of the capacitor and the dielectric film.

### SUMMARY

The present disclosure provides a semiconductor memory device that includes a capacitor that may increase capacitance.

According to an aspect of the present disclosure, there is provided a semiconductor memory device comprising a conductive pattern disposed on a substrate, a lower electrode connected to the conductive pattern, and extending in a first direction, wherein the lower electrode includes a lower pattern and an upper pattern, wherein the lower electrode is disposed between the upper pattern and the conductive pattern, a capacitor dielectric film disposed on the lower electrode and an upper electrode disposed on the capacitor dielectric film, wherein the lower pattern includes a lower inner interface extending in the first direction, wherein the upper pattern is free of an inner interface extending in the first direction.

According to an aspect of the present disclosure, there is provided a semiconductor memory device comprising a conductive pattern disposed on a substrate, a lower electrode connected to the conductive pattern, and extending in a first direction, wherein the lower electrode includes a lower pattern and an upper pattern, wherein the lower electrode is disposed between the upper pattern and the conductive pattern, a lower electrode support supporting the lower electrode and in contact with a sidewall of the lower pattern, a capacitor dielectric film disposed on the lower electrode and the lower electrode support and an upper electrode disposed on the capacitor dielectric film, wherein the lower electrode support includes an upper surface and a bottom surface opposite to each other in the first direction, wherein the bottom surface of the lower electrode support faces the conductive pattern, wherein the upper pattern protrudes in the first direction beyond the upper surface of the lower electrode support, wherein at a boundary of the lower pattern and the upper pattern, a first crystal direction of the lower pattern is different from a second crystal direction of the upper pattern.

According to an aspect of the present disclosure, there is provided a semiconductor memory device comprising a substrate including an active area defined by an element isolation film and extending in a first direction, wherein the active area includes a first portion and a second portion defined on each of both opposing sides of the first portion, a word-line disposed within the substrate and the element isolation film, and extending in a second direction different from the first direction, wherein the word-line extends across an area between the first portion of the active area and the second portion of the active area, a bit-line contact connected to the first portion of the active area, a bit-line disposed on the bit-line contact and connected to the bit-line contact, wherein the bit-line extends in a third direction different from the first direction and the second direction, a landing pad connected to the second portion of the active area and a capacitor, wherein the capacitor includes a lower electrode connected to the landing pad and extending in the third direction, a capacitor dielectric film disposed on the lower electrode and an upper electrode disposed on the capacitor dielectric film, wherein the lower electrode includes a lower pattern connected to the landing pad and an upper pattern disposed on the lower pattern, wherein the lower pattern includes a lower inner interface extending in the third direction, wherein the upper pattern is free of an inner interface extending in the third direction.

Purposes according to the present disclosure are not limited to the above-mentioned purpose. Other purposes and advantages according to the present disclosure that are not mentioned may be understood based on following descriptions, and may be more clearly understood based on implementations according to the present disclosure. Further, it will be easily understood that the purposes and advantages according to the present disclosure may be realized using means shown in the claims or combinations thereof.

### BRIEF DESCRIPTION OF THE DRAWINGS

The above and other aspects and features of the present disclosure will become more apparent by describing in detail illustrative implementations thereof with reference to the attached drawings, in which:

FIG. 1 is an example diagram for illustrating a semiconductor memory device according to some implementations.

FIG. 2 is an enlarged view of a portion P of FIG. 1.

FIG. 3 is an enlarged view of a portion Q of FIG. 1.

FIG. 4 is a schematic diagram for illustrating a crystal direction of a conductive material in a R portion of FIG. 2.

FIG. 5 and FIG. 6 are diagrams for illustrating semiconductor memory devices according to some implementations, respectively.

FIGS. 7 to 9 are diagrams for illustrating semiconductor memory devices according to some implementations, respectively.

FIG. 10 and FIG. 11 are diagrams for illustrating semiconductor memory devices according to some implementations, respectively.

FIG. 12 and FIG. 13 are diagrams for illustrating a semiconductor memory device according to some implementations.

FIG. 14 and FIG. 15 are diagrams for illustrating a semiconductor memory device according to some implementations.

FIG. 16 is a layout of a semiconductor memory device according to some implementations.

FIG. 17 is a layout showing only a word-line and a cell active area in FIG. 16.

FIG. 18 is a cross-sectional view cut along A-A in FIG. 16.

FIG. 19 and FIG. 20 are diagrams for illustrating a semiconductor memory device according to some implementations.

FIG. 21 is a layout diagram for illustrating a semiconductor memory device according to some implementations.

FIG. 22 is a perspective view for illustrating a semiconductor memory device according to some implementations.

FIG. 23 is a cross-sectional view cut along lines B-B and C-C of FIG. 21.

FIG. 24 is a layout diagram for illustrating a semiconductor memory device according to some implementations.

FIG. 25 is a perspective view for illustrating a semiconductor memory device according to some implementations.

FIG. 26 is a diagram for illustrating a semiconductor memory device according to some implementations.

FIGS. 27 to 31 are diagrams of intermediate structures corresponding to intermediate step of a semiconductor memory device manufacturing method according to some implementations.

FIGS. 32 to 35 are diagrams of intermediate structures corresponding to intermediate step of a semiconductor memory device manufacturing method according to some implementations.

### DETAILED DESCRIPTION

For simplicity and clarity of illustration, elements in the drawings are not necessarily drawn to scale. The same reference numbers in different drawings represent the same or similar elements, and as such perform similar functionality. Further, descriptions and details of well-known steps and elements are omitted for simplicity of the description. Furthermore, in the following detailed description of the present disclosure, numerous specific details are set forth in order to provide a thorough understanding of the present disclosure. However, it will be understood that the present disclosure may be practiced without these specific details. In other instances, well-known methods, procedures, components, and circuits have not been described in detail so as not to unnecessarily obscure aspects of the present disclosure. Examples of various implementations are illustrated and described further below. It will be understood that the description herein is not intended to limit the claims to the specific implementations described. On the contrary, it is intended to cover alternatives, modifications, and equivalents as may be included in the spirit and scope of the present disclosure as defined by the appended claims.

A shape, a size, a ratio, an angle, a number, etc. disclosed in the drawings for illustrating implementations of the present disclosure are illustrative, and the present disclosure is not limited thereto. The same reference numerals refer to the same elements herein. Further, descriptions and details of well-known steps and elements are omitted for simplicity of the description. Furthermore, in the following detailed description of the present disclosure, numerous specific details are set forth in order to provide a thorough understanding of the present disclosure. However, it will be understood that the present disclosure may be practiced without these specific details. In other instances, well-known methods, procedures, components, and circuits have not been described in detail so as not to unnecessarily obscure aspects of the present disclosure.

The terminology used herein is for the purpose of describing particular implementations only and is not intended to limit the present disclosure. As used herein, the singular forms “a” and “an” are intended to include the plural forms as well, unless the context clearly indicates otherwise. It will be further understood that the terms “comprise”, “comprising”, “include”, and “including” when used in this specification, specify the presence of the stated features, integers, operations, elements, and/or components, but do not preclude the presence or addition of one or more other features, integers, operations, elements, components, and/or portions thereof. As used herein, the term “and/or” includes any and all combinations of one or more of the associated listed items. Expression such as “at least one of” when preceding a list of elements may modify an entirety of list of elements and may not modify the individual elements of the list. When referring to “C to D”, this means C inclusive to D inclusive unless otherwise specified.

It will be understood that, although the terms “first”, “second”, “third”, and so on may be used herein to illustrate various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described under could be termed a second element, component, region, layer or section, without departing from the spirit and scope of the present disclosure.

In addition, it will also be understood that when a first element or layer is referred to as being present “on” or “beneath” a second element or layer, the first element may be disposed directly on or beneath the second element or may be disposed indirectly on or beneath the second element with a third element or layer being disposed between the first and second elements or layers. It will be understood that when an element or layer is referred to as being “connected to”, or “coupled to” another element or layer, it may be directly on, connected to, or coupled to the other element or layer, or one or more intervening elements or layers may be present. In addition, it will also be understood that when an element or layer is referred to as being “between” two elements or layers, it may be the only element or layer between the two elements or layers, or one or more intervening elements or layers may also be present.

Further, as used herein, when a layer, film, region, plate, or the like may be disposed “on” or “on a top” of another layer, film, region, plate, or the like, the former may directly contact the latter or still another layer, film, region, plate, or the like may be disposed between the former and the latter. As used herein, when a layer, film, region, plate, or the like is directly disposed “on” or “on a top” of another layer, film, region, plate, or the like, the former directly contacts the latter and still another layer, film, region, plate, or the like is not disposed between the former and the latter. Further, as used herein, when a layer, film, region, plate, or the like may be disposed “below” or “under” another layer, film, region, plate, or the like, the former may directly contact the latter or still another layer, film, region, plate, or the like may be disposed between the former and the latter. As used herein, when a layer, film, region, plate, or the like is directly disposed “below” or “under” another layer, film, region, plate, or the like, the former directly contacts the latter and still another layer, film, region, plate, or the like is not disposed between the former and the latter.

Unless otherwise defined, all terms including technical and scientific terms used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

In one example, when a certain implementation may be implemented differently, a function or operation specified in a specific block may occur in a sequence different from that specified in a flowchart. For example, two consecutive blocks may be actually executed at the same time. Depending on a related function or operation, the blocks may be executed in a reverse sequence.

In descriptions of temporal relationships, for example, temporal precedent relationships between two events such as “after”, “subsequent to”, “before”, etc., another event may occur therebetween unless “directly after”, “directly subsequent” or “directly before” is not indicated. The features of the various implementations of the present disclosure may be partially or entirely combined with each other, and may be technically associated with each other or operate with each other. The implementations may be implemented independently of each other and may be implemented together in an association relationship. Spatially relative terms, such as “beneath,” “below,” “lower,” “under,” “above,” “upper,” and the like, may be used herein for ease of illustration to illustrate one element or feature's relationship to another element or feature as illustrated in the figures. It will be understood that the spatially relative terms are intended to encompass different orientations of the device in use or in operation, in addition to the orientation depicted in the figures. For example, when the device in the drawings may be turned over, elements described as “below” or “beneath” or “under” other elements or features would then be oriented “above” the other elements or features. Thus, the example terms “below” and “under” may encompass both an orientation of above and below. The device may be otherwise oriented, for example, rotated 90 degrees or at other orientations, and the spatially relative descriptors used herein should be interpreted accordingly.

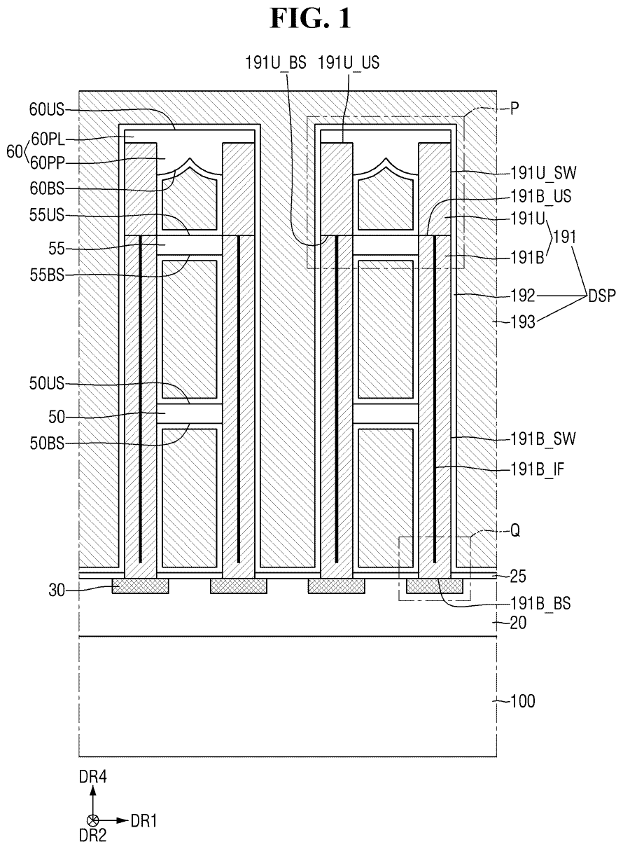

Referring to FIGS. 1 to 4, a semiconductor memory device according to some implementations is described.

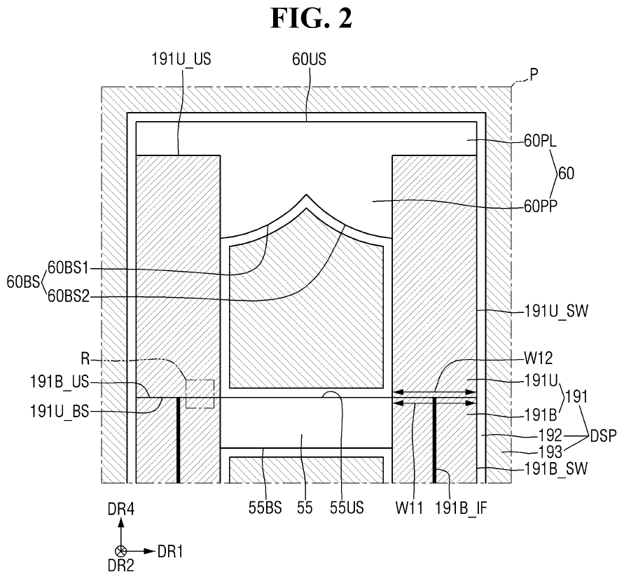

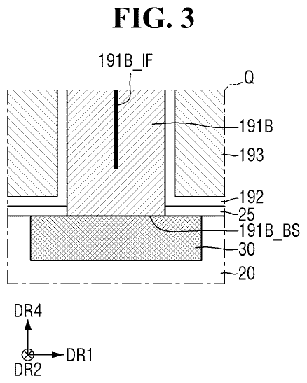

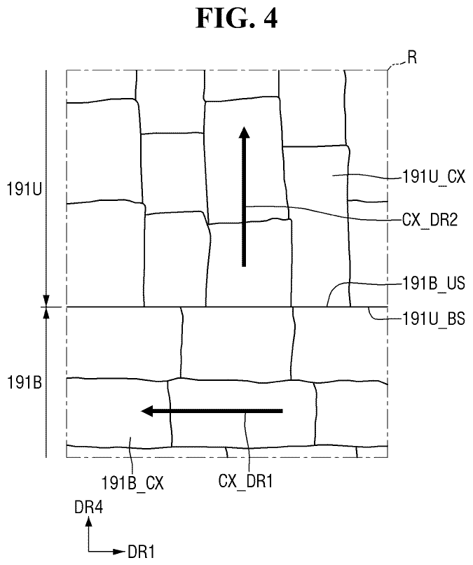

FIG. 1 is an example diagram for illustrating a semiconductor memory device according to some implementations. FIG. 2 is an enlarged view of a portion P of FIG. 1. FIG. 3 is an enlarged view of a portion Q of FIG. 1. FIG. 4 is a schematic diagram for illustrating a crystal direction of a conductive material in a R portion of FIG. 2.

Referring to FIGS. 1 to 4, a semiconductor memory device according to some implementations may include a conductive pattern 30, a lower electrode 191, a capacitor dielectric film 192, an upper electrode 193, at least one lower electrode support 50 and 55, and a first upper electrode support 60.

The conductive pattern 30 may be disposed on a substrate 100. The conductive pattern 30 is shown as being isolated from substrate 100. This is only for convenience of illustration, and the present disclosure is not limited thereto. Unlike what is shown, the conductive pattern 30 may be electrically connected to a conductive area formed on or within the substrate 100.

An interlayer insulating film 20 may be disposed on the substrate 100. The conductive pattern 30 may be disposed within the interlayer insulating film 20.

The substrate 100 may be made of bulk silicon or SOI (silicon-on-insulator). Alternatively, the substrate 100 may be a silicon substrate, or may include a material other than silicon, such as, but not limited to, silicon germanium, SGOI (silicon germanium on insulator), indium antimonide, lead telluride compound, indium arsenide, indium phosphide, gallium arsenide, or gallium antimonide. In a following description, an example in which the substrate 100 is embodied as a silicon substrate is described.

For example, the interlayer insulating film 20 may include at least one of a silicon oxide film, a silicon nitride film, a silicon oxynitride film (SiON), a silicon oxycarbonitride film (SiOCN), a silicon carbonitride film (SiCN), and a combination thereof.

The conductive pattern 30 includes conductive material. The conductive pattern 30 may include at least one of, for example, a doped semiconductor material, a conductive metal nitride, a conductive metal silicon nitride, a metal carbonitride, a conductive metal silicide, a conductive metal oxide, a two-dimensional material (2D material), and a metal. In a semiconductor memory device according to some implementations, the two-dimensional material may be a metallic material and/or a semiconductor material. The two-dimensional material may include a two-dimensional allotrope or a two-dimensional compound. For example, the two-dimensional material may include, but is not limited to, at least one of graphene, molybdenum disulfide (MoS₂), molybdenum diselenide (MoSe₂), tungsten diselenide (WSe₂), and tungsten disulfide (WS₂). That is, the above-described two-dimensional materials are only listed by way of example. The two-dimensional material that may be included in the semiconductor device according to the present disclosure is not limited to the above-described materials.

A first etch stop film 25 may be disposed on the interlayer insulating film 20. The first etch stop film 25 may not cover at least a portion of the conductive pattern 30 so as to allow a portion of the conductive pattern 30 to be exposed.

In one example, the first etch stop film 25 may be disposed on the conductive pattern 30. The first etch stop film 25 may include a lower electrode hole exposing at least a portion of the conductive pattern 30.

For example, the first etch stop film 25 may include at least one of a silicon nitride film, a silicon carbonitride film, a silicon boronitride film (SiBN), a silicon carbonate film (SiCO), a silicon oxynitride film, and a silicon oxycarbonitride film. For example, the silicon carbonate film (SiCO) refers to containing silicon (Si), carbon (C), and oxygen (O), but does not imply a ratio between contents of silicon (Si), carbon (C), and oxygen (O).

A data storage pattern DSP may be disposed on the conductive pattern 30. The data storage pattern DSP may be electrically connected to the conductive pattern 30.

In one example, the data storage patterns DSP may be capacitors. The data storage pattern DSP may include a lower electrode 191, a capacitor dielectric film 192, and an upper electrode 193.

A plurality of lower electrodes 191 may be disposed on the conductive pattern 30. The lower electrode 191 may be connected to the conductive pattern 30. A portion of the lower electrode 191 may be disposed within the first etch stop film 25.

For example, each lower electrode 191 may have a pillar shape. The lower electrode 191 may extend in an elongated manner in a fourth direction DR4 which is a thickness direction of the substrate 100. A length by which the lower electrode 191 extends in the fourth direction DR4 is greater than a length by which the lower electrode 191 extends in each of directions DR1 and DR2 parallel to the upper surface of the substrate 100. For example, the first direction DR1 and the second direction DR2 may be perpendicular to the fourth direction DR4.

For example, the plurality of lower electrodes 191 may be arranged repeatedly along the first direction DR1. Although not shown, the lower electrodes 191 may be arranged iteratively along the second direction DR2. The first direction DR1 and the second direction DR2 may be orthogonal to each other. The present disclosure is not limited thereto. The first direction DR1 and the second direction DR2 may be directions parallel to the surface of the substrate 100, and may be perpendicular to the fourth direction DR4.

The lower electrode 191 may include a lower pattern 191B and an upper pattern 191U. Each of the lower pattern 191B of the lower electrode and the upper pattern 191U of the lower electrode may extend in an elongated manner in the fourth direction DR4.

The lower pattern 191B of the lower electrode is connected to the conductive pattern 30. The lower pattern 191B of the lower electrode is disposed between the conductive pattern 30 and the upper pattern 191U of the lower electrode. For example, the lower pattern 191B and the upper pattern 191U of the lower electrode may be in contact with each other.

The lower pattern 191B of the lower electrode may include an upper surface 191B_US and a bottom surface 191B_BS opposite to each other in the fourth direction DR4. The bottom surface 191B_BS of the lower pattern of the lower electrode faces the conductive pattern 30. The bottom surface 191B_BS of the lower pattern of the lower electrode is connected to the conductive pattern 30.

The upper pattern 191U of the lower electrode may include an upper surface 191U_US and a bottom surface 191U_BS opposite to each other in the fourth direction DR4. The bottom surface 191U_BS of the upper pattern of the lower electrode faces the conductive pattern 30. The bottom surface 191U_BS of the upper pattern of the lower electrode is connected to the upper surface 191B_US of the lower pattern of the lower electrode. The bottom surface 191U_BS of the upper pattern of the lower electrode may contact the upper surface 191B_US of the lower pattern of the lower electrode.

The bottom surface 191B_BS of the lower pattern of the lower electrode may be a bottom surface of the lower electrode 191. The upper surface 191U_US of the upper pattern of the lower electrode may be an upper surface of the lower electrode 191.

For example, at a boundary between the lower pattern 191B of the lower electrode and the upper pattern 191U of the lower electrode, a width W11 of the lower pattern 191B of the lower electrode in the first direction DR1 may be equal to a width W12 of the upper pattern 191U of the lower electrode in the first direction DR1.

A width of the lower pattern 191B of the lower electrode is shown to be constant as the lower pattern extends away from the conductive pattern 30. This is only for convenience of illustration and the present disclosure is not limited thereto. Unlike what is shown, the width of the lower pattern 191B of the lower electrode may vary as it extends away from the conductive pattern 30. In a semiconductor memory device according to some implementations, the width of the upper pattern 191U of the lower electrode may be constant as it extends away from the conductive pattern 30.

The lower pattern 191B of the lower electrode includes a lower inner interface 191B_IF. The lower inner interface 191B_IF may extend in an elongated manner in the fourth direction DR4 and within the lower pattern 191B of the lower electrode.

The lower inner interface 191B_IF may extend to the upper surface 191B_US of the lower pattern of the lower electrode. The lower inner interface 191B_IF may extend to the bottom surface 191U_BS of the upper pattern of the lower electrode.

The lower inner interface 191B_IF may not extend to the bottom surface 191B_BS of the lower pattern of the lower electrode. The lower inner interface 191B_IF may not extend to the upper surface of conductive pattern 30. An upper surface of the conductive pattern 30 may contact the lower pattern 191B of the lower electrode.

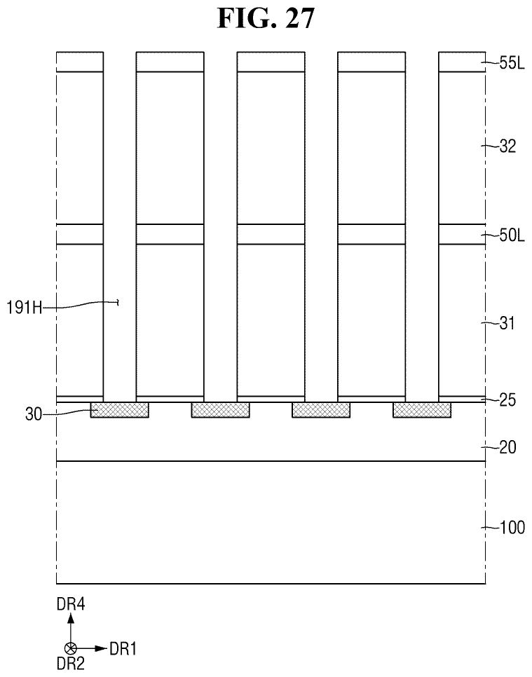

While the lower pattern 191B of the lower electrode is formed within a lower electrode hole (191H in FIG. 27), the lower inner interface 191B_IF may be formed. The lower inner interface 191B_IF may be formed when the lower patterns 191B of the lower electrode respectively deposited on both opposing sidewalls of the lower electrode hole 191H meet each other.

The upper pattern 191U of the lower electrode does not include an inner interface extending to the fourth direction DR4. A method of depositing the upper pattern 191U of the lower electrode is different from a method of depositing the lower pattern 191B of the lower electrode. Due to this difference in the deposition method, the upper pattern 191U of the lower electrode does not include the inner interface extending in the fourth direction DR4.

At a boundary between the upper pattern 191U of the lower electrode and the lower pattern 191B of the lower electrode, the crystal direction of the lower pattern 191B of the lower electrode is different from the crystal direction of the upper pattern 191U of the lower electrode. For example, the crystal direction of the upper pattern 191U of the lower electrode may mean a direction in which a crystal of the conductive material contained in the upper pattern 191U of the lower electrode has been grown.

In FIG. 4, the lower pattern 191B of the lower electrode may include a plurality of lower conductive material crystals 191B_CX. The lower pattern 191B of the lower electrode may be a collection of the plurality of lower conductive material crystals 191B_CX. At the boundary of the upper pattern 191U of the lower electrode and the lower pattern 191B of the lower electrode, the lower conductive material crystal 191B_CX may be grown in a first crystal direction CX_DR1. At the boundary between the upper pattern 191U of the lower electrode and the lower pattern 191B of the lower electrode, a crystal direction of the lower pattern 191B of the lower electrode may be the first crystal direction CX_DR1. For example, at the boundary between the upper pattern 191U of the lower electrode and the lower pattern 191B of the lower electrode, the crystal direction CX_DR1 of the lower pattern 191B of the lower electrode may be the first direction DR1.

The upper pattern 191U of the lower electrode may include a plurality of upper conductive material crystals 191U_CX. The upper pattern 191U of the lower electrode may be a collection of the plurality of upper conductive material crystals 191U_CX. At the boundary of the upper pattern 191U of the lower electrode and the lower pattern 191B of the lower electrode, the upper conductive material crystal 191U_CX may be grown in a second crystal direction CX_DR2. At the boundary between the upper pattern 191U of the lower electrode and the lower pattern 191B of the lower electrode, the crystal direction of the upper pattern 191U of the lower electrode may be the second crystal direction CX_DR2. For example, at the boundary between the upper pattern 191U of the lower electrode and the lower pattern 191B of the lower electrode, the crystal direction CX_DR2 of the upper pattern 191U of the lower electrode may be the fourth direction DR4.

Through various analyses, a person skilled in the art of the present disclosure may easily identify the crystal direction of the lower conductive material crystal 191B_CX and the crystal direction of the upper conductive material crystal 191U_CX.

The lower pattern 191B of the lower electrode may include, for example, a conductive metal nitride such as titanium nitride, tantalum nitride, niobium nitride or tungsten nitride, a metal such as ruthenium, iridium, titanium or tantalum, and a conductive metal oxide such as iridium oxide or niobium oxide, etc. The present disclosure is not limited thereto. In the semiconductor memory device according to some implementations, the lower pattern 191B of the lower electrode may include titanium nitride (TiN). Moreover, in the semiconductor memory device according to some implementations, the lower pattern 191B of the lower electrode may include niobium nitride (NbN).

The upper pattern 191U of the lower electrode may include a conductive material capable of selective growth. The upper pattern 191U of the lower electrode may include, for example, one of titanium nitride (TiN), titanium (Ti), tungsten (W), molybdenum (Mo), ruthenium (Ru) and cobalt (Co). The present disclosure is not limited thereto.

In one example, the lower pattern 191B of the lower electrode and the upper pattern 191U of the lower electrode may include the same material. For example, the lower pattern 191B of the lower electrode and the upper pattern 191U of the lower electrode may include titanium nitride (TiN). In this case, in FIG. 4, each of the lower conductive material crystal 191B_CX and the upper conductive material crystal 191U_CX may be titanium nitride crystal.

In another example, the lower pattern 191B of the lower electrode and the upper pattern 191U of the lower electrode may include different materials.

After forming a lower electrode hole within a mold insulating film, a lower electrode may be formed by filling the lower electrode hole with a conductive material. When the lower electrode is formed using this method, in order to increase a vertical dimension of the lower electrode, a vertical dimension of the mold insulating film should be increased. As the vertical dimension of the mold insulating film increases, bowing of the lower electrode hole may become worse. Moreover, an area of the conductive pattern 30 exposed through the lower electrode hole may be reduced, so that a contact area between the lower electrode and the conductive pattern may be reduced. As a result, performance and reliability of the semiconductor memory device may deteriorate.

When the upper pattern 191U of the lower electrode is formed using selective growth, the problem caused by increasing the vertical dimension of the mold insulating film may be reduced or prevented. The vertical dimension of the lower electrode 191 in the fourth direction DR4 may be increased without the above-mentioned problem, such that the capacitance of the capacitor may be increased. Thus, the performance and reliability of the semiconductor memory device may be improved.

The at least one lower electrode support 50 and 55 may be disposed on the first etch stop film 25. The at least one lower electrode support 50 and 55 may support the lower electrode 191.

For example, a plurality of lower electrode supports 50 and 55 may be disposed on the first etch stop film 25. The plurality of lower electrode supports 50 and 55 may include the first lower electrode support 50 and the second lower electrode support 55 sequentially disposed on the first etch stop film 25.

The first lower electrode support 50 and the second lower electrode support 55 may be spaced from the first etch stop film 25 in the fourth direction DR4. The first lower electrode support 50 and the second lower electrode support 55 may be spaced apart from each other in the fourth direction DR4.

For example, the second lower electrode support 55 may be a lower electrode support spaced furthest from the conductive pattern 30 in the fourth direction DR4 among the lower electrode supports 50 and 55. The second lower electrode support 55 may be the uppermost lower electrode support.

Each of the first lower electrode support 50 and the second lower electrode support 55 may be in contact with lower electrode 191. Each of the first lower electrode support 50 and the second lower electrode support 55 may be in contact with the lower pattern 191B of the lower electrode. Each of the first lower electrode support 50 and the second lower electrode support 55 may contact a portion of a sidewall 191B_SW of the lower pattern of the lower electrode.

The number of lower electrode supports in contact with the sidewall 191B_SW of the lower pattern of the lower electrode is shown to be two. However, this is only for convenience of illustration and the present disclosure is not limited thereto.

The first lower electrode support 50 may include an upper surface 50US and a bottom surface 50BS opposite to each other in the fourth direction DR4.

The second lower electrode support 55 may include the upper surface 55US and bottom surface 55BS opposite to each other in the fourth direction DR4. Each of the bottom surface 50BS of the first lower electrode support and the bottom surface 55BS of the second lower electrode support may face the conductive pattern 30.

For example, each of the bottom surface 50BS of the first lower electrode support and the bottom surface 55BS of the second lower electrode support may be flat in a cross-sectional view. Each of the upper surface 50US of the first lower electrode support and the upper surface 55US of the second lower electrode support may be flat in the cross-sectional view.

The upper pattern 191U of the lower electrode protrudes in the fourth direction DR4 beyond the lower electrode support 50 and 55. The upper pattern 191U of the lower electrode may protrude in the fourth direction DR4 beyond the upper surface 55US of the second lower electrode support.

Each of the first lower electrode support 50 and the second lower electrode support 55 may include at least one of, for example, silicon nitride, silicon carbonitride, silicon boronitride, silicon carbonate, silicon oxynitride, and silicon oxycarbonitride. In FIG. 1, a thickness of the second lower electrode support 55 in the fourth direction DR4 is shown to be equal to a thickness of the first lower electrode support 50. The present disclosure is not limited thereto. Unlike what is shown, the thickness of the second lower electrode support 55 in the fourth direction DR4 may be different from the thickness of the first lower electrode support 50.

The first upper electrode support 60 may be disposed on the lower electrode 191. The first upper electrode support 60 may support the lower electrode 191.

The first upper electrode support 60 may be disposed on the upper pattern 191U of the lower electrode. The first upper electrode support 60 may be in contact with the upper pattern 191U of the lower electrode.

The first upper electrode support 60 may be disposed on the second lower electrode support 55. The first upper electrode support 60 may be spaced apart from the second lower electrode support 55 in the fourth direction DR4.

In the semiconductor memory device according to some implementations, the first upper electrode support 60 may contact an upper surface 191U_US of the upper pattern of the lower electrode and a sidewall 191U_SW of the upper pattern of the lower electrode. The first upper electrode support 60 may cover a portion of the sidewall 191U_SW of the upper pattern of the lower electrode. The first upper electrode support 60 does not contact a sidewall 191B_SW of the lower pattern of the lower electrode.

For example, the first upper electrode support 60 may include a plate portion 60PL and a protrusion 60PP. The protrusion 60PP of the first upper electrode support may protrude from the plate portion 60PL of the first upper electrode support in the fourth direction DR4.

The plate portion 60PL of the first upper electrode support may contact the upper surface 191U_US of the upper pattern of the lower electrode. The protrusion 60PP of the first upper electrode support may contact the sidewall 191U_SW of the upper pattern of the lower electrode. For example, the protrusion 60PP of the first upper electrode support and the plate portion 60PL of the first upper electrode support may be distinguished from each other based on the upper surface 191U_US of the upper pattern of the lower electrode.

A thickness of the protrusion 60PP of the first upper electrode support in the fourth direction DR4 may change as the protrusion 60PP extends away from the upper pattern 191U of the lower electrode. For example, the thickness of the protrusion 60PP of the first upper electrode support in the fourth direction DR4 may decrease and then increase as it extends away from a first sidewall of the upper pattern 191U of the lower electrode.

It is assumed that the first upper electrode support 60 is in contact with a first lower electrode and a second lower electrode adjacent to each other. In a cross-sectional view, the thickness of the protrusion 60PP of the first upper electrode support may be smallest in a center portion of a space between the first lower electrode and the second lower electrode.

The first upper electrode support 60 may include an upper surface 60US and a bottom surface 60BS opposite to each other in the fourth direction DR4. The bottom surface 60BS of the first upper electrode support may face the second lower electrode support 55.

The plate portion 60PL of the first upper electrode support may include the upper surface 60US of the first upper electrode support. The protrusion 60PP of the first upper electrode support may include the bottom surface 60BS of the first upper electrode support.

For example, in a cross-sectional view, the upper surface 60US of the first upper electrode support may be flat. In the cross-sectional view, the bottom surface 60BS of the first upper electrode support may include a plurality of inclined surfaces. The bottom surface 60BS of the first upper electrode support may include a first bottom inclined surface 60BS1 and a second bottom inclined surface 60BS2. Each of the first bottom inclined surface 60BS1 and the second bottom inclined surface 60BS2 may be an inclined curved surface. Unlike what is shown, each of the first bottom inclined surface 60BS1 and the second bottom inclined surface 60BS2 may be an inclined flat surface.

The first upper electrode support 60 may include, for example, at least one of silicon nitride, silicon carbonitride, silicon boronitride, silicon carbonate, silicon oxynitride, and silicon oxycarbonitride.

The capacitor dielectric film 192 may be disposed on the lower electrode 191. The capacitor dielectric film 192 may be disposed on the lower electrode support 50 and 55 and the first upper electrode support 60.

The capacitor dielectric film 192 may extend along the sidewalls 191U_SW, 191B_SW of the lower electrode, the upper surface 60US of the first upper electrode support, and the bottom surface 60BS of the first upper electrode support. Since the upper surface 191U_US of the upper pattern of the lower electrode is in contact with the first upper electrode support 60, the capacitor dielectric film 192 may not extend along the upper surface 191U_US of the upper pattern of the lower electrode.

The capacitor dielectric film 192 may extend along the upper surface 50US of the first lower electrode support, the bottom surface 50BS of the first lower electrode support, the upper surface 65US of the second lower electrode support, and the bottom surface 55BS of the second lower electrode support.

For example, the capacitor dielectric film 192 may include at least one of silicon oxide, silicon nitride, silicon oxynitride, hafnium oxide, hafnium silicon oxide, hafnium zirconium oxide, hafnium aluminum oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, lead zirconium titanium oxide, yttrium oxide, aluminum oxide, lead scandium tantalum oxide, lead zinc niobate, and combinations thereof. However, the present disclosure is not limited thereto.

In one example, the capacitor dielectric film 192 may include a stacked film structure in which a zirconium oxide film, an aluminum oxide film, and a zirconium oxide film are sequentially stacked. In another example, the capacitor dielectric film 192 may include a dielectric film including hafnium (Hf). The description of the capacitor dielectric film 192 as set forth above is only an example, and the present disclosure is not limited thereto.

The capacitor dielectric film 192 may include at least one of a ferroelectric material, an antiferroelectric material, and a paraelectric material. For example, the capacitor dielectric film 192 may include at least one of a ferroelectric material, an antiferroelectric material, a paraelectric material, a combination of a ferroelectric material and an antiferroelectric material, a combination of a ferroelectric material and a paraelectric material, a combination of a paraelectric material and an antiferroelectric material, or a combination of a ferroelectric material, an antiferroelectric material, and a paragenetic material.

Unlike what is described above, the data storage pattern DSP may be embodied as a variable resistance pattern that may be switched between two resistance states under an electrical pulse applied to the memory element. For example, the data storage pattern DSP may include a phase-change material whose crystal state changes depending on an amount of current, a perovskite compound, a transition metal oxide, a magnetic material, a ferromagnetic material, or an antiferromagnetic material.

The upper electrode 193 may be disposed on the capacitor dielectric film 192. The upper electrode 193 may fill a space between adjacent lower electrodes 191. The upper electrode 193 may fill a space between the first upper electrode support 60 and the second lower electrode support 55, and a space between the lower electrode supports 50 and 55 adjacent to each other in the fourth direction DR4. The upper electrode 193 may fill a space between the first lower electrode support 50 and the interlayer insulating film 20.

The upper electrode 193 may include, for example, a doped semiconductor material, a conductive metal nitride such as titanium nitride, tantalum nitride, niobium nitride or tungsten nitride, etc., a metal such as ruthenium, iridium, titanium or tantalum, etc. and a conductive metal oxide such as iridium oxide or niobium oxide, etc. The present disclosure is not limited thereto.

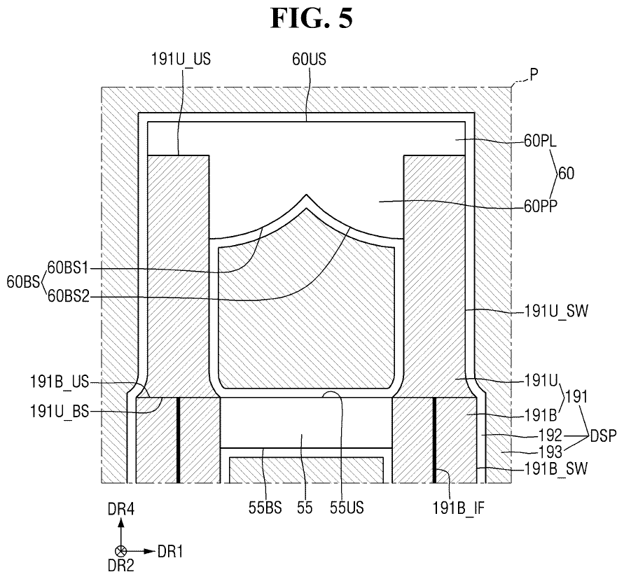

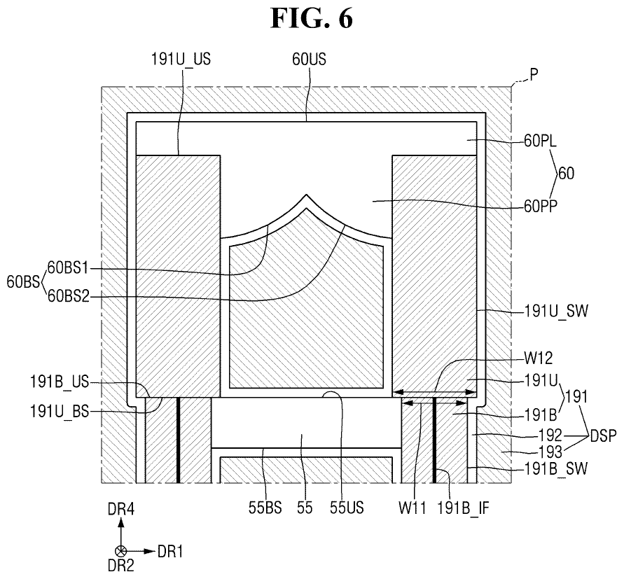

FIG. 5 and FIG. 6 are diagrams for illustrating semiconductor memory devices according to some implementations, respectively. For convenience, the following description focuses on differences thereof from the descriptions set forth above using FIG. 1 to FIG. 4.

For reference, each of FIG. 5 and FIG. 6 is an enlarged view of a portion P of FIG. 1.

Referring to FIG. 5, in the semiconductor memory device according to some implementations, the width of the upper pattern 191U of the lower electrode may change as the upper pattern 191U extends away from the conductive pattern 30.

For example, the width of the upper pattern 191U of the lower electrode may decrease and then be constant as the upper pattern 191U extends away from the conductive pattern 30.

Unlike what is shown, in one example, the width of the upper pattern 191U of the lower electrode may increase and then be constant as the upper pattern 191U extends away from the conductive pattern 30. In another example, the width of the upper pattern 191U of the lower electrode may decrease as it extends away from the conductive pattern 30.

Referring to FIG. 6, in the semiconductor memory device according to some implementations, at the boundary between the lower pattern 191B of the lower electrode and the upper pattern 191U of the lower electrode, the width W11 of the lower pattern 191B of the lower electrode in the first direction DR1 may be smaller than the width W12 in the first direction DR1 of the upper pattern 191U of the lower electrode in the first direction DR1.

The width of the upper pattern 191U of the lower electrode may be constant as it extends away from the conductive pattern 30. The present disclosure is not limited thereto.

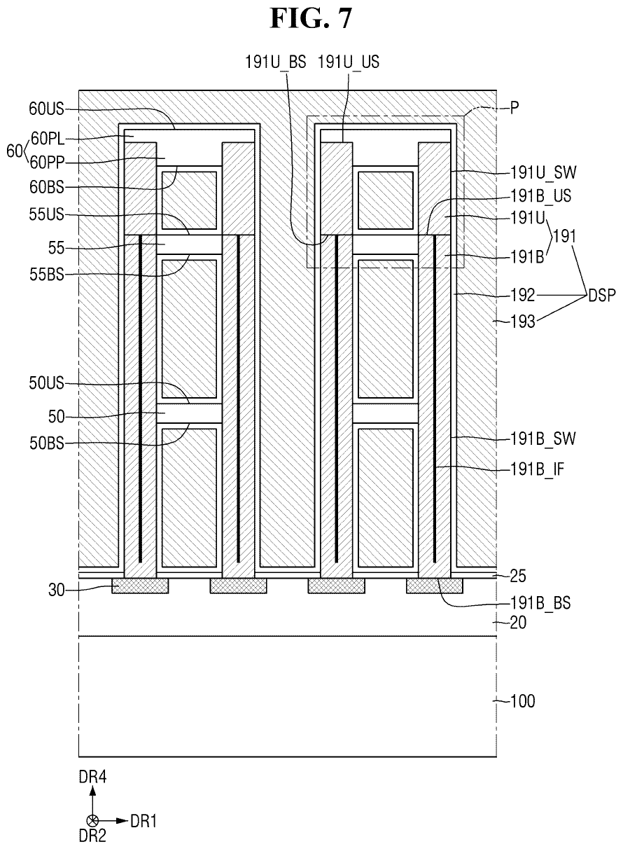

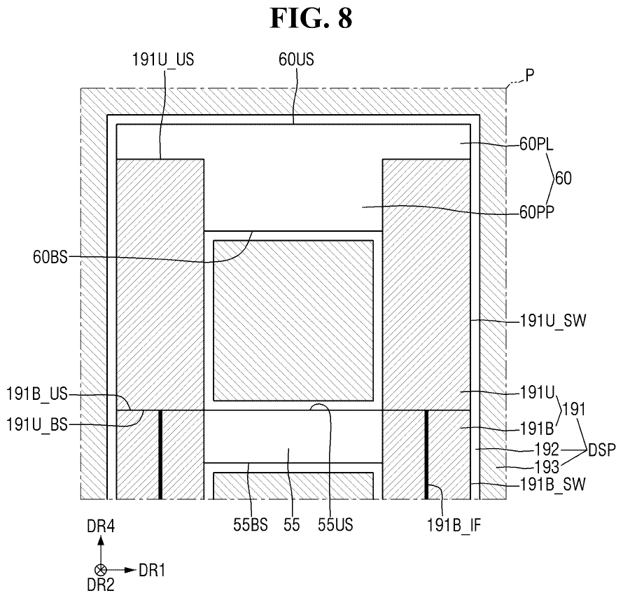

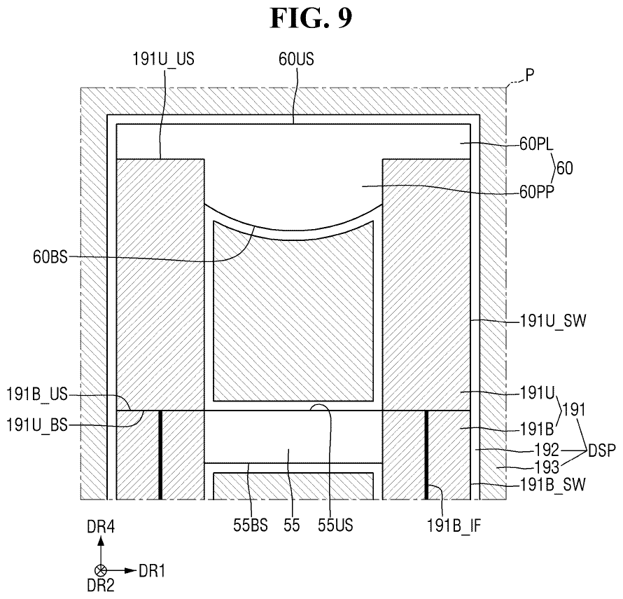

FIGS. 7 to 9 are diagrams for illustrating semiconductor memory devices according to some implementations, respectively. For convenience, the following description focuses on differences thereof from the descriptions as set forth above using FIG. 1 to FIG. 4. For reference, each of FIG. 8 and FIG. 9 is an enlarged view of a portion P of FIG. 7.

Referring to FIGS. 7 to 9, in the semiconductor memory device according to some implementations, the bottom surface 60BS of the first upper electrode support does not include the plurality of inclined surfaces.

In FIG. 8, in a cross-sectional view, the bottom surface 60BS of the first upper electrode support may be flat. The thickness of the protrusion 60PP of the first upper electrode support in the fourth direction DR4 may be constant as the protrusion 60PP extends away from the upper pattern 191U of the lower electrode.

In FIG. 9, in the cross-sectional view, the bottom surface 60BS of the first upper electrode support may be a convex curved surface. The thickness of the protrusion 60PP of the first upper electrode support in the fourth direction DR4 may increase and then decrease as the protrusion extends away from the upper pattern 191U of the lower electrode.

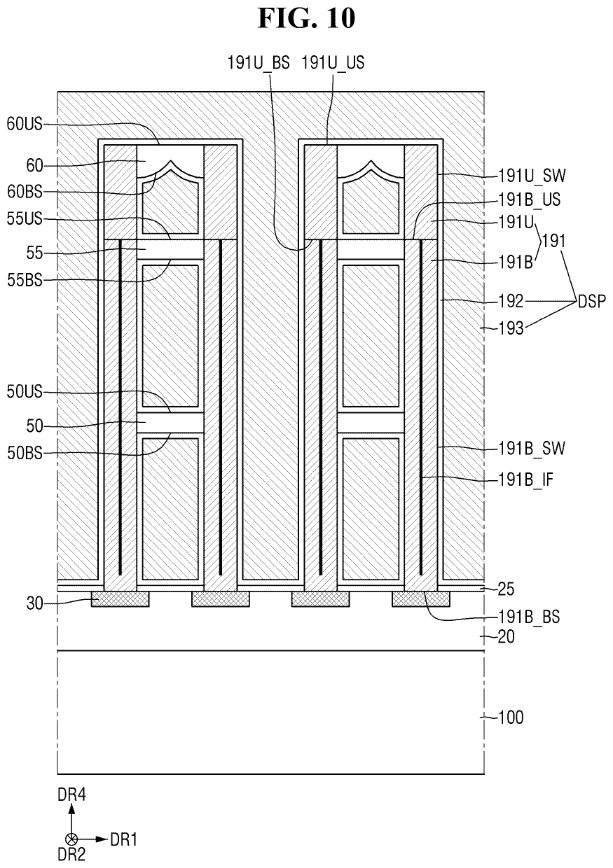

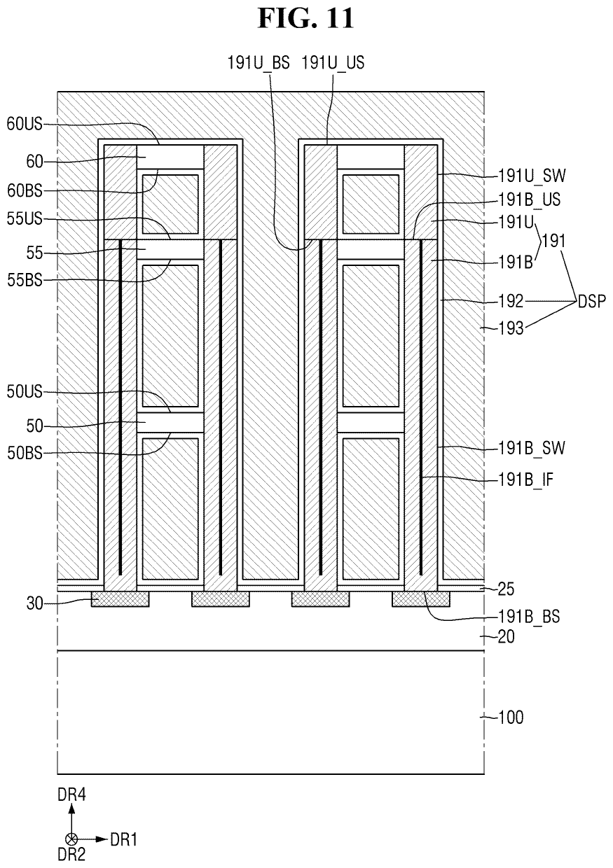

FIG. 10 and FIG. 11 are diagrams for illustrating semiconductor memory devices according to some implementations, respectively. For convenience, the following description focuses on differences from the description as set forth above using FIGS. 1 to 9.

Referring to FIG. 10 and FIG. 11, in the semiconductor memory device according to some implementations, the first upper electrode support 60 does not cover the upper surface 191U_US of the upper pattern of the lower electrode.

The first upper electrode support 60 does not contact the upper surface 191U_US of the upper pattern of the lower electrode. The first upper electrode support 60 does not include the plate portion (60PL in FIG. 1 and FIG. 7) of the first upper electrode support.

The capacitor dielectric film 192 may extend along the upper surface 191U_US of the upper pattern of the lower electrode. The capacitor dielectric film 192 may be in contact with the upper surface 191U_US of the upper pattern of the lower electrode.

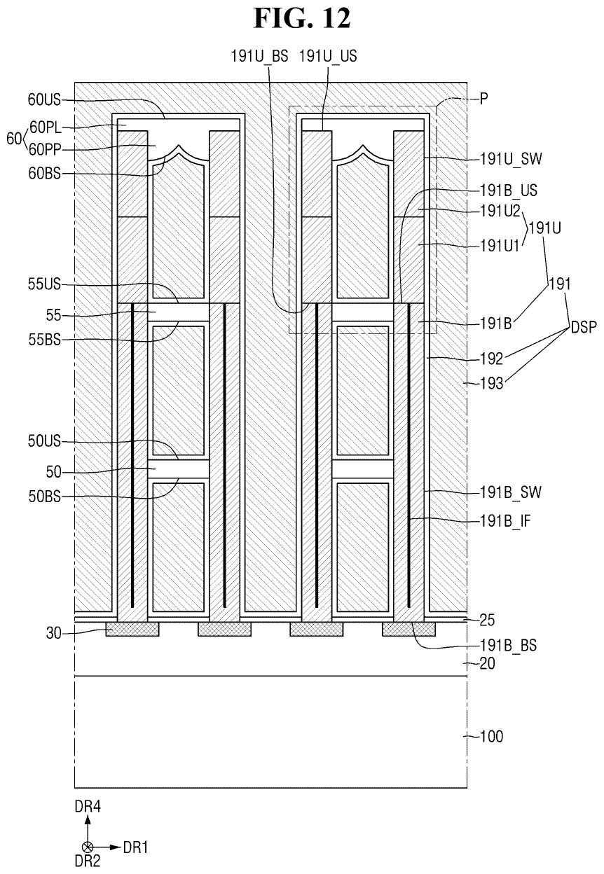

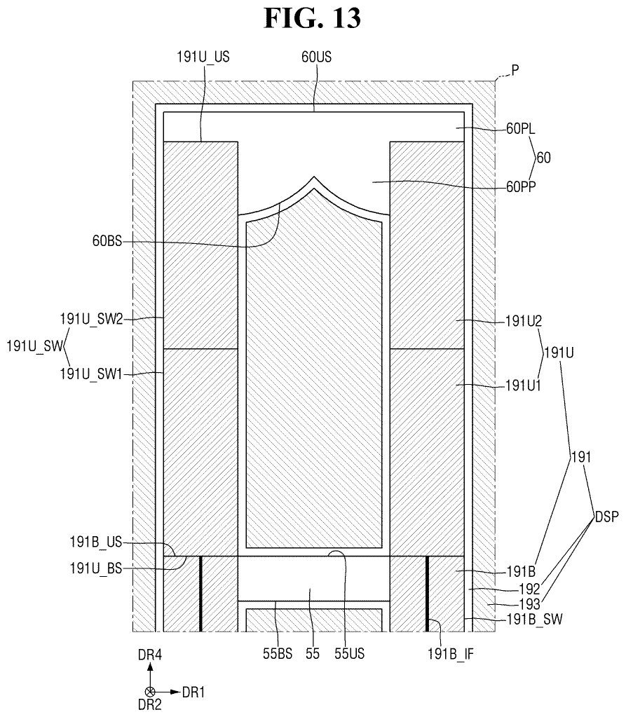

FIG. 12 and FIG. 13 are diagrams for illustrating a semiconductor memory device according to some implementations. For convenience, the following description focuses on differences thereof from the descriptions as set forth above using FIG. 1 to FIG. 4.

For reference, FIG. 13 is an enlarged view of a portion P of FIG. 12.

Referring to FIG. 12 and FIG. 13, in the semiconductor memory device according to some implementations, the upper pattern 191U of the lower electrode may include a plurality of sub-upper patterns 191U1 and 191U2 stacked in the fourth direction DR4 while being disposed on the lower pattern 191B of the lower electrode.

The upper pattern 191U of the lower electrode may include the first sub-upper pattern 191U1 and the second sub-upper pattern 191U2. The upper pattern 191U of the lower electrode is shown as including two sub-upper patterns. This is only for convenience of illustration and the present disclosure is not limited thereto.

The first sub-upper pattern 191U1 may be disposed between the lower electrode 191B and the second sub-upper pattern 191U2. The first sub-upper pattern 191U1 may contact the lower electrode 191B and the second sub-upper pattern 191U2.

The first upper electrode support 60 may be in contact with the second sub-upper pattern 191U2. The first upper electrode support 60 may not come into contact with the first sub-upper pattern 191U1.

The sidewall 191U_SW of the upper pattern of the lower electrode may include a first portion 191U_SW1 defined by the first sub-upper pattern 191U1 and a second portion 191U_SW2 defined by the second sub-upper pattern 191U2.

The first upper electrode support 60 may not be in contact with the first portion 191U_SW1 of the sidewall of the upper pattern of the lower electrode. The first upper electrode support 60 may be in contact with the second portion 191U_SW2 of the sidewall of the upper pattern of the lower electrode.

Each of the first sub-upper pattern 191U1 and the second sub-upper pattern 191U2 may include a conductive material capable of selective growth. In one example, the first sub-upper pattern 191U1 and the second sub-upper pattern 191U2 may include the same conductive material.

In another example, the first sub-upper pattern 191U1 and the second sub-upper pattern 191U2 may include different conductive materials.

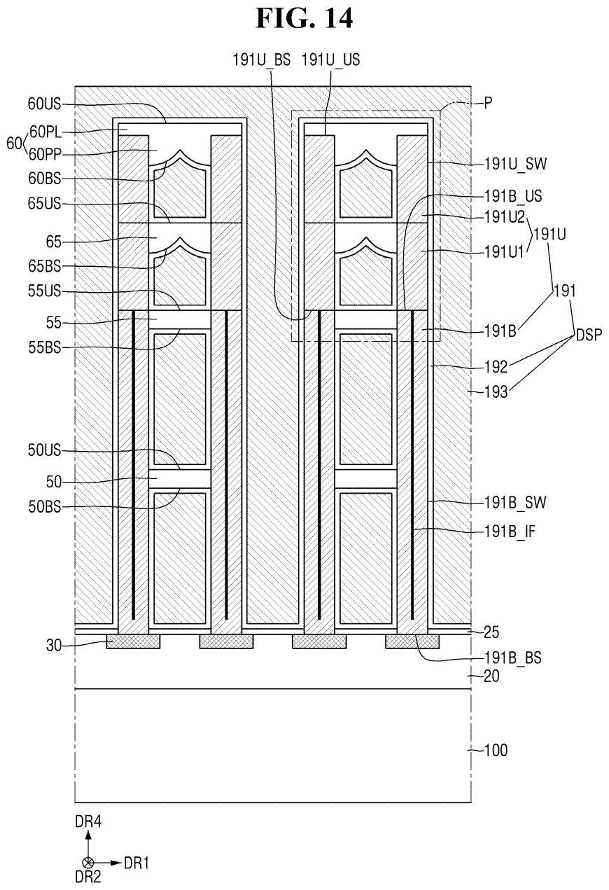

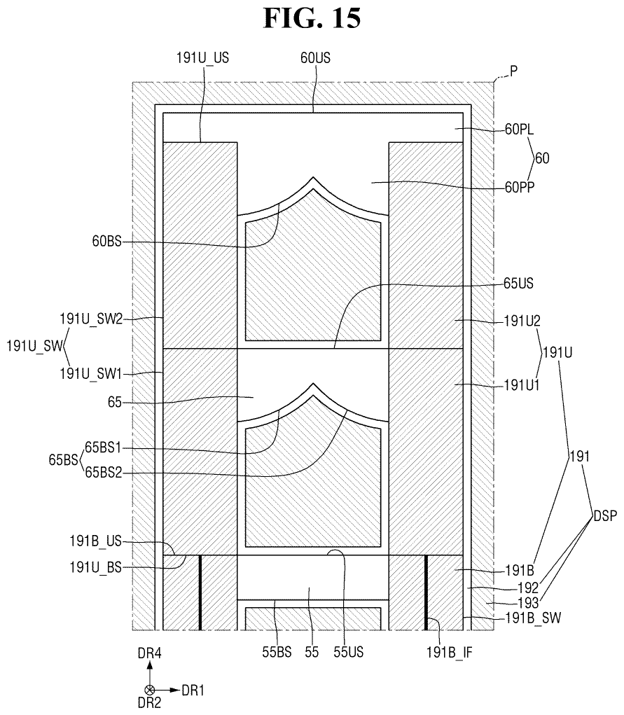

FIG. 14 and FIG. 15 are diagrams for illustrating a semiconductor memory device according to some implementations. For convenience, the following description focuses on differences thereof from the descriptions as set forth above using FIGS. 1 to 4, FIG. 12, and FIG. 13.

For reference, FIG. 15 is an enlarged view of a portion P of FIG. 14.

Referring to FIG. 14 and FIG. 15, the semiconductor memory device according to some implementations may further include a second upper electrode support 65 disposed between the first upper electrode support 60 and the conductive pattern 30.

The second upper electrode support 65 may be disposed between the first upper electrode support 60 and the second lower electrode support 55. The second upper electrode support 65 may support the lower electrode 191.

The second upper electrode support 65 may be spaced apart from the first upper electrode support 60 in the fourth direction DR4. The second upper electrode support 65 may be spaced from the second lower electrode support 55 in the fourth direction DR4.

The second upper electrode support 65 may be in contact with the upper pattern 191U of the lower electrode. For example, the second upper electrode support 65 may contact the first sub-upper pattern 191U1.

The second upper electrode support 65 may be in contact with the sidewall 191U_SW of the upper pattern of the lower electrode. The second upper electrode support 65 may be in contact with the first portion 191U_SW1 of the sidewall of the upper pattern of the lower electrode. The second upper electrode support 65 may not be in contact with the second portion 191U_SW2 of the sidewall of the upper pattern of the lower electrode.

A thickness of the second upper electrode support 65 in the fourth direction DR4 may change as the second upper electrode support 65 extends away from the upper pattern 191U of the lower electrode. The thickness of the second upper electrode support 65 in the fourth direction DR4 may decrease and then increase as the second upper electrode support 65 extends away from the upper pattern 191U of the lower electrode.

The second upper electrode support 65 may include an upper surface 65US and a bottom surface 65BS opposite to each other in the fourth direction DR4. The bottom surface 65BS of the second upper electrode support may face the second lower electrode support 55.

The second sub-upper pattern 191U2 may protrude in the fourth direction DR4 beyond the upper surface 65US of the second upper electrode support. For example, in a cross-sectional view, the upper surface 65US of the second upper electrode support may be flat.

In the cross-sectional view, the bottom surface 65BS of the second upper electrode support may include a plurality of inclined surfaces. The bottom surface 65BS of the second upper electrode support may include a third bottom inclined surface 65BS1 and a fourth bottom inclined surface 65BS2. Each of the third bottom inclined surface 65BS1 and the fourth bottom inclined surface 65BS2 may be a curved inclined surface. Unlike what is shown, each of the third bottom inclined surface 65BS1 and the fourth bottom inclined surface 65BS2 may be a flat inclined surface.

The second upper electrode support 65 may include, for example, at least one of silicon nitride, silicon carbonitride, silicon boronitride, silicon carbonate, silicon oxynitride, and silicon oxycarbonitride.

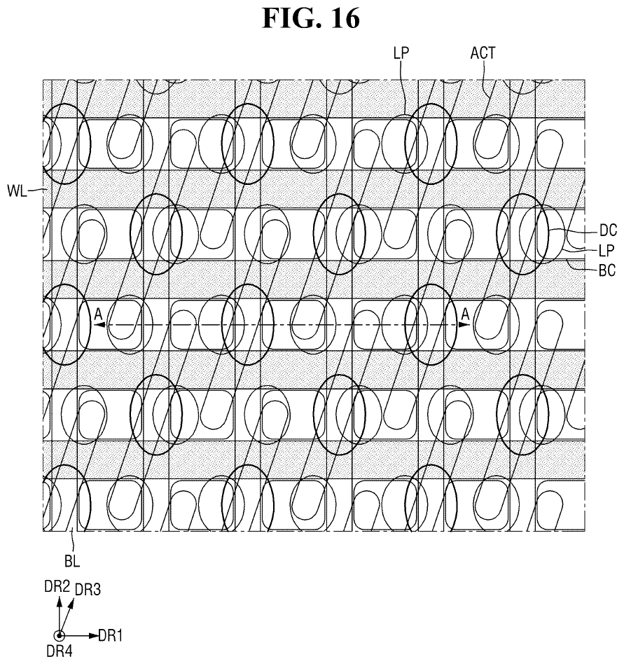

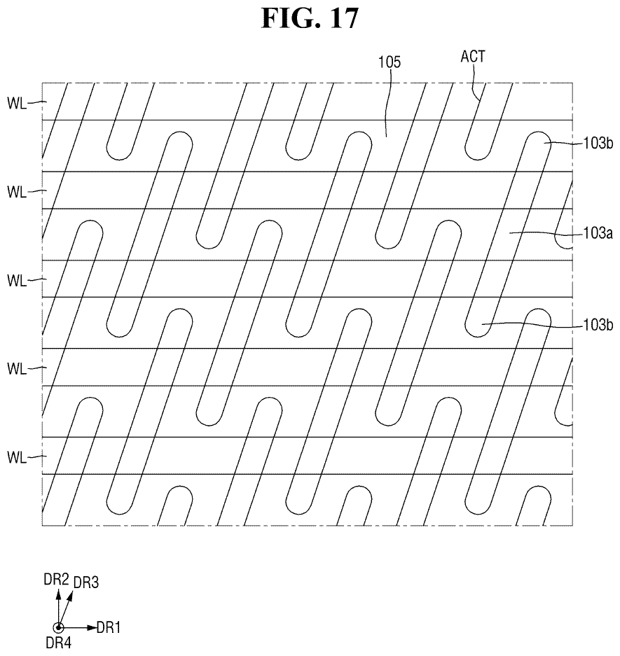

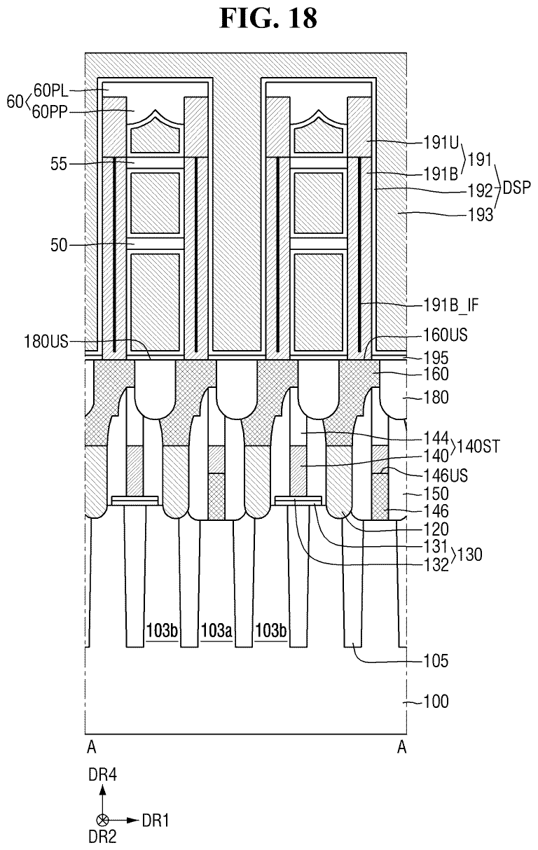

FIG. 16 is a layout of a semiconductor memory device according to some implementations. FIG. 17 is a layout showing only a word-line and a cell active area in FIG. 16. FIG. 18 is a cross-sectional view cut along A-A in FIG. 16.

For reference, FIG. 16 shows an example layout of DRAM (Dynamic Random Access Memory) excluding the data storage pattern DSP. The present disclosure is not limited thereto.

Moreover, the first direction DR1 in FIG. 16 corresponds to the first direction DR1 in FIG. 1. The second direction DR2 in FIG. 16 may correspond to the second direction DR2 in FIG. 1. The present disclosure is not limited thereto. Unlike what is described above, the first direction DR1 in FIG. 16 may correspond to the second direction DR2 in FIG. 1, and the second direction DR2 in FIG. 16 may correspond to the first direction DR1 in FIG. 1.

Referring to FIG. 16 and FIG. 17, the semiconductor memory device according to some implementations may include a plurality of cell active areas ACT.

The cell active area ACT may be defined by a cell element isolation film 105 formed within the substrate (100 of FIG. 18). According to a reduction of the design rule of the semiconductor memory device, the cell active area ACT may extend in a form of a bar extending in a diagonal line or an oblique line, as shown. For example, the cell active area ACT may extend in the third direction DR3.

A plurality of gate electrodes may extend across the cell active area ACT in the first direction DR1. The plurality of gate electrodes may extend parallel to each other. For example, the plurality of gate electrodes may be a plurality of word-lines WL. The word-lines WL may be spaced apart from each other by an equal spacing. A width of each of the word-lines WL or the spacing between the word-lines WL may be determined according to the design rule.

The two word-lines WL extending in the first direction DR1 may divide each cell active area ACT into three portions. The cell active area ACT may include a storage connection area 103b and a bit-line connection area 103a. The bit-line connection area 103a may be located in a middle portion of the cell active area ACT, while the storage connection area 103b may be located at each of both opposing ends of the cell active area ACT.

For example, the bit-line connection area 103a may be an area connected to the bit-line BL, and the storage connection area 103b may be an area connected to the data storage pattern (DSP in FIG. 18). In other words, the bit-line connection area 103a may correspond to a common drain area, and the storage connection area 103b may correspond to a source area. Each word-line WL and the bit-line connection area 103a and the storage connection area 103b adjacent thereto may constitute a transistor.

On the word-line WL, a plurality of bit-lines BL extending in the second direction DR2 orthogonal to the word-line WL may be disposed. The plurality of bit-lines BL may extend parallel to each other. The bit-lines BL may be spaced apart from each other by an equal spacing. A width of the bit-line BL or the spacing between the bit-lines BL may be determined according to the design rule.

The fourth direction DR4 may be perpendicular to the first direction DR1, the second direction DR2, and the third direction DR3.

The semiconductor memory device according to some implementations may include various contact arrangements formed on the cell active area ACT. The various contact arrangements may include, for example, a direct contact DC, a buried contact BC, and a landing pad LP.

In this regard, the direct contact DC may mean a contact that electrically connects the cell active area ACT and the bit-line BL to each other. The buried contact BC may mean a contact that connects the cell active area ACT to the lower electrode (191 in FIG. 18) of the data storage pattern (DSP in FIG. 18).

Due to the arrangement structure, a contact area between the buried contact BC and the cell active area ACT may be small. Accordingly, a conductive landing pad LP may be introduced to increase the contact area thereof with the cell active area ACT and a contact area thereof with the lower electrode (191 in FIG. 18) of the data storage pattern.

In the semiconductor memory device according to some implementations, the landing pad LP may be disposed between the buried contact BC and the lower electrode (191 of FIG. 18) of the data storage pattern. The contact area may be increased via the introduction of the landing pad LP, such that contact resistance between the cell active area ACT and the lower electrode (191 in FIG. 13) of the data storage pattern may be reduced.

For example, the conductive pattern 30 in FIG. 1, FIG. 7, FIG. 10 to FIG. 12, and FIG. 14 may correspond to the landing pad LP.

In the semiconductor memory device according to some implementations, the direct contact DC may be disposed so as to overlap a central portion of the cell active area ACT. The buried contact BC may be disposed so as to overlap each of both opposing ends of the cell active area ACT. The direct contact DC may be connected to the bit-line connection area 103a. The buried contact BC may be connected to the storage connection area 103b.

As the buried contact BC is disposed so as to overlap each of both opposing ends of the cell active area ACT, the landing pad LP may be disposed adjacent to each of both opposing ends of the cell active area ACT and may overlap a portion of the buried contact BC. In other words, the buried contact BC may be formed to overlap a portion of the cell active area ACT and a portion of the element isolation film (105 in FIG. 18) between adjacent word-lines WL and adjacent bit-lines BL.

The word-line WL may be buried within the substrate 100. The word-line WL may extend across a portion of the active area ACT between the direct contact DC and the buried contact BC.

As shown, two word-lines WL may extend across one active area ACT. As the active area ACT extends in a diagonal direction, the word-line WL may have an angle less than 90 degree with respect to the active area ACT.

The direct contacts DC may be arranged symmetrically. The buried contacts BC may be arranged symmetrically. Thus, the direct contacts DC may be arranged in a straight line along each of the first direction DR1 and the second direction DR2. The buried contacts BC may be arranged in a straight line along each of the first direction DR1 and the second direction DR2.

In one example, unlike the direct contact DC and the buried contact BC, the landing pads LP may be arranged in a zigzag form in the second direction DR2 where the bit-line BL extends. Further, the landing pads LP may be arranged in the first direction D1 in which the word-line WL extends so as to overlap the same side portions of corresponding bit-lines BL, respectively.

For example, the landing pads LP arranged in a first line in the first direction may overlap left side portions of corresponding bit-lines BL, respectively. The landing pads LP arranged in a second line in the first direction may overlap right side portions of corresponding bit-lines BL, respectively.

Referring to FIGS. 16 to 18, the semiconductor memory device according to some implementations may include a plurality of bit-line structures 140ST, a plurality of storage contacts 120, a plurality of bit-line contacts 146, and the date storage pattern DSP.

The cell element isolation film 105 may be disposed within the substrate 100. The cell element isolation film 105 may have an STI (shallow trench isolation) structure with excellent element isolation ability. The cell element isolation film 105 may define the cell active area ACT in the memory cell area.

The cell active area ACT defined by the cell element isolation film 105 may have an elongated island shape including a minor axis and a major axis as shown in FIG. 16 and FIG. 17. The cell active area ACT may have an oblique shape to have an angle smaller than 90 degrees with respect to the word-line WL formed in the element isolation film 105. Further, the cell active area ACT may have an oblique shape to have an angle smaller than 90 degrees with respect to the bit-line BL formed on the element isolation film 105.

The cell element isolation film 105 may include, for example, at least one of a silicon oxide film, a silicon nitride film, and a silicon oxynitride film. However, the present disclosure is not limited thereto.

The element isolation film 105 is shown to be formed as one insulating film. However, this is only for convenience of illustration. The present disclosure is not limited thereto. Depending on a spacing between adjacent cell active areas ACT, the cell element isolation film 105 may be formed as one insulating film, or may be formed as a plurality of insulating films.

In FIG. 18, an upper surface of the cell element isolation film 105 and the upper surface of the substrate 100 are shown as being coplanar with each other. However, this is only for convenience of illustration. The present disclosure is not limited thereto.

The bit-line structure 140ST may include a cell conductive line 140, a cell line capping film 144, and a bit-line spacer 150.

The cell conductive line 140 may be disposed on the substrate 100 and the cell element isolation film 105 in which the word-line WL is formed. The cell conductive line 140 may intersect with the cell element isolation film 105 and the cell active area ACT defined by the cell element isolation film 105. The cell conductive line 140 may intersect the word-line WL. In this regard, the cell conductive line 140 may correspond to the bit-line BL. For example, the cell conductive line 140 may be the bit-line BL in FIG. 16.

For example, the cell conductive line 140 may include at least one of a semiconductor material doped with impurities, a conductive silicide compound, a conductive metal nitride, a two-dimensional (2D material), and a metal.

The cell conductive line 140 is shown to be embodied as a single film. This is only for convenience of illustration and the present disclosure is not limited thereto. That is, unlike what is shown, the cell conductive line 140 may include a stack of a plurality of conductive films.

The cell line capping film 144 may be disposed on the cell conductive line 140. The cell line capping film 144 may extend along an upper surface of the cell conductive line 140 and in the second direction DR2. For example, the cell line capping film 144 may include at least one of a silicon nitride film, silicon oxynitride, silicon carbonitride, and silicon oxycarbonitride.

In the semiconductor memory device according to some implementations, the cell line capping film 144 may include a silicon nitride film. Although the cell line capping film 144 is shown to be embodied as a single film, the present disclosure is not limited thereto.

The bit-line spacer 150 may be disposed on a sidewall of each of the cell conductive line 140 and the cell line capping film 144. The bit-line spacer 150 extends in an elongated manner in the second direction DR2.

The bit-line spacer 150 is shown to be embodied as a single film. This is only for convenience of illustration and the present disclosure is not limited thereto. That is, in another example, unlike what is shown, the bit-line spacer 150 may have a multilayer structure. The bit-line spacer 150 may include, for example, a silicon oxide film, a silicon nitride film, a silicon oxynitride film (SiON), a silicon oxycarbonitride film (SiOCN), air, and a combination thereof. However, the present disclosure is not limited thereto.

A cell insulating film 130 may be disposed on the substrate 100 and the cell element isolation film 105. More specifically, the cell insulating film 130 may be disposed on an upper surface of the substrate 100 and the cell element isolation film 105 in an area in which the bit-line contact 146 and the storage contact 120 are not formed. The cell insulating film 130 may be formed between the substrate 100 and the cell conductive line 140, and between the cell element isolation film 105 and the cell conductive line 140.

The cell insulating film 130 may be a single film. However, as shown, the cell insulating film 130 may be embodied as a stack of films including a first cell insulating film 131 and a second cell insulating film 132. For example, the first cell insulating film 131 may include a silicon oxide film, and the second cell insulating film 132 may include a silicon nitride film. The present disclosure is not limited thereto. Unlike what is shown, the cell insulating film 130 may be embodied as a stack of triple films including a silicon oxide film, a silicon nitride film, and a silicon oxide film. The present disclosure is not limited thereto.

The bit-line contact 146 may be disposed between the cell conductive line 140 and the substrate 100. The cell conductive line 140 may be disposed on the bit-line contact 146.

The bit-line contact 146 may be disposed between the bit-line connection portion 103a of the cell active area ACT and the cell conductive line 140. The bit-line contact 146 may electrically connect the cell conductive line 140 and the substrate 100 to each other. The bit-line contact 146 may be connected to the bit-line connection portion 103a.

The bit-line contact 146 may include an upper surface 146US connected to the cell conductive line 140. It is shown that as the bit-line contact extends away from the upper surface 146US of the bit-line contact, a width of the bit-line contact 146 in the first direction DR1 is constant. This is only for convenience of illustration and the present disclosure is not limited thereto.

The bit-line contact 146 may correspond to the direct contact DC. For example, bit-line contact 146 may include at least one of a semiconductor material doped with an impurity, a conductive metal silicide, a conductive metal nitride, a conductive metal oxide, a metal, and a metal alloy.

In an area in which the cell conductive line 140 overlaps the bit-line contact 146, the bit-line spacer 150 may be disposed on the substrate 100 and the cell element isolation film 105. The bit-line spacer 150 may be disposed on a sidewall of each of the cell conductive line 140, the cell line capping film 144, and the bit-line contact 146.

In a remaining area in which the cell conductive line 140 non-overlaps the bit-line contact 146, the bit-line spacer 150 may be disposed on the cell insulating film 130. The bit-line spacer 150 may be disposed on a sidewall of each of the cell conductive line 140 and the cell line capping film 144.

The storage contact 120 may be disposed between cell conductive lines 140 adjacent to each other in the first direction DR1. The storage contact 120 may be disposed on each of both opposing sides of the cell conductive line 140. More specifically, the storage contact 120 may be disposed between bit-line structures 140ST. The storage contact 120 may be disposed between word-lines WL adjacent to each other in the second direction DR2.

The storage contact 120 may overlap the substrate 100 and the cell element isolation film 105 in an area between adjacent cell conductive lines 140. The storage contact 120 may be connected to the cell active area ACT. More specifically, the storage contact 120 may be connected to the storage connection portion 103b. In this regard, the storage contact 120 may correspond to the buried contact (BC in FIG. 16).

For example, the storage contact 120 may include at least one of a semiconductor material doped with impurities, a conductive silicide compound, a conductive metal nitride, a conductive metal carbide, a conductive metal carbonitride, a conductive metal oxide, and a metal.

A storage pad 160 may be disposed on the storage contact 120. The storage pad 160 may be electrically connected to the storage contact 120. The storage pad 160 may be connected to the storage connection portion 103b of the cell active area ACT. In this regard, the storage pad 160 may correspond to the landing pad (LP in FIG. 16).

The storage pad 160 may overlap a portion of an upper surface of the bit-line structure 140ST. For example, the storage pad 160 may include at least one of a conductive silicide compound, a conductive metal nitride, a conductive metal carbide, a conductive metal oxide, and a metal.

A pad isolation insulating film 180 may be disposed on the storage pad 160 and the bit-line structure 140ST. For example, the pad isolation insulating film 180 may be disposed on the cell line capping film 144.

The pad isolation insulating film 180 may define the storage pad 160 as each of a plurality of isolated areas. The pad isolation insulating film 180 may not cover the upper surface 160US of the storage pad. For example, a vertical level of an upper surface 160US of the storage pad based on the upper surface of the substrate 100 may be equal to a vertical level of an upper surface 180US of the pad isolation insulating film based on the upper surface of the substrate 100.

The pad isolation insulating film 180 includes an insulating material and may electrically insulate the plurality of storage pads 160 from each other. For example, the pad isolation insulating film 180 may include at least one of a silicon oxide film, a silicon nitride film, a silicon oxynitride film, a silicon oxycarbonitride film, and a silicon carbonitride film. The present disclosure is not limited thereto.

A second etch stop film 195 may be disposed on the upper surface 160US of the storage pad and the upper surface 180US of the pad isolation insulating film. For example, the second etch stop film 195 may correspond to the first etch stop film 25 in FIG. 1, FIG. 7, FIG. 10 to FIG. 12, FIG. 14.

For example, the second etch stop film 195 may include at least one of silicon nitride SiN, silicon carbonitride (SiCN), silicon oxycarbonitride (SiOCN), silicon oxycarbide (SiOC), and silicon boron nitride (SiBN).

The data storage pattern DSP may be disposed on the storage pad 160. The data storage pattern DSP is electrically connected to the storage pad 160. A portion of the data storage pattern DSP may be disposed within the second etch stop film 195.

The data storage pattern DSP may include, for example, a capacitor. The data storage pattern DSP includes the lower electrode 191, the capacitor dielectric film 192, and the upper electrode 193. The lower electrode 191 may include the lower pattern 191B of the lower electrode and the upper pattern 191U of the lower electrode.

The first and second lower electrode supports 50 and 55 may support the lower electrode 191. The first and second lower electrode supports 50 and 55 may be in contact with the lower pattern 191B of the lower electrode.

The first upper electrode support 60 may be disposed on the lower electrode 191. The first upper electrode support 60 may be in contact with the upper pattern 191U of the lower electrode.

The descriptions about the lower electrode 191, the capacitor dielectric film 192, and the upper electrode 193 may be substantially the same as those set forth above using FIGS. 1 to 15 and, thus, are omitted below.

The descriptions about the first and second lower electrode supports 50 and 55 and the first upper electrode support 60 may be substantially the same as those set forth above using FIGS. 1 to 15 and, thus, are omitted below.

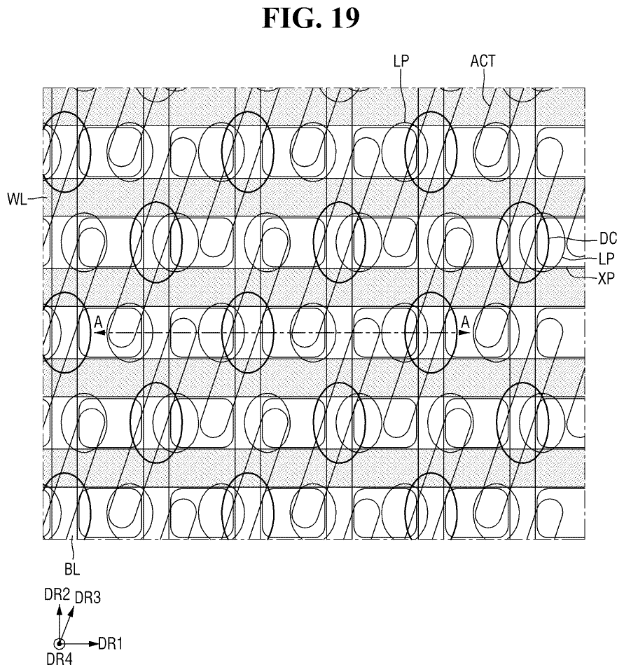

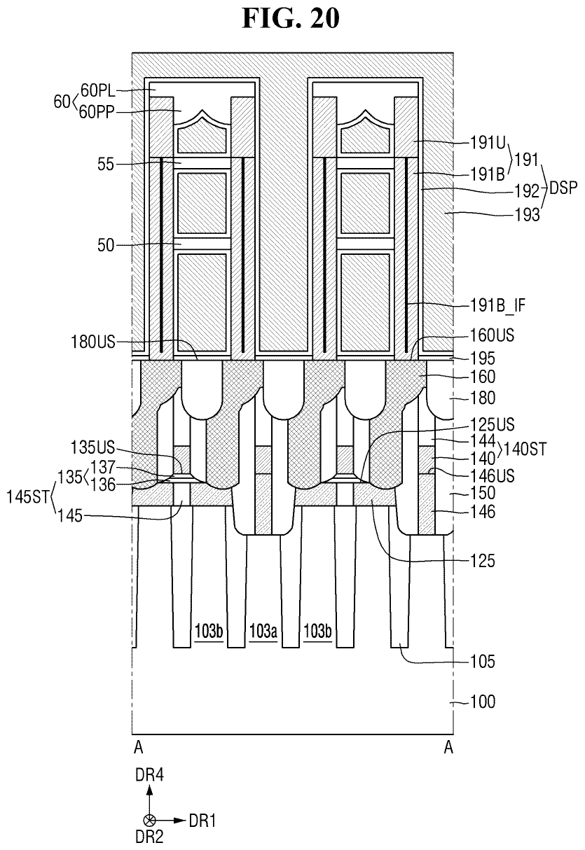

FIG. 19 and FIG. 20 are diagrams for illustrating a semiconductor memory device according to some implementations. For convenience, following description is based on differences thereof from the descriptions set forth above using FIG. 16 to FIG. 18.

For reference, FIG. 19 is a layout of a semiconductor memory device according to some implementations. FIG. 20 is a cross-sectional view cut along A-A in FIG. 19.

Referring to FIG. 17, FIG. 19, and FIG. 20, the semiconductor memory device according to some implementations may include a node pad XP disposed on the substrate 100.

The node pad XP may be disposed in place of the buried contact BC in FIG. 16. The node pad XP may be a contact pad that connects the cell active area ACT to the lower electrode 191 of the data storage pattern DSP. The node pad XP may be connected to the storage connection area 103b.

Due to the structural arrangement, a contact area between the node pad XP and the cell active area ACT may be small. Accordingly, a conductive landing pad LP may be introduced to expand a contact area with the cell active area ACT and the lower electrode 191 of the data storage pattern DSP.

As the node pad XP is disposed so as to overlap each of both opposing end portions of the cell active area ACT, the landing pad LP may be disposed adjacent to each of both opposing ends of the cell active area ACT and overlap at least a portion of the node pad XP. In other words, the node pad XP may be formed to overlap the cell active area ACT and cell element isolation film 105 in an area between adjacent word-lines WL and area between adjacent bit-lines BL.

The word-line WL may extend across a portion of the cell active area ACT between the direct contact DC and the node pad XP. The direct contacts DC may be arranged symmetrically. The node pads XP may be arranged symmetrically. Thus, the direct contacts DC may be arranged in a straight line along each of the first direction DR1 and the second direction DR2. The node pads XP may be arranged in a straight line along each of the first direction DR1 and the second direction DR2.

A node contact pad 125 may be disposed on the substrate 100 and the cell element isolation film 105. The node contact pad 125 may be disposed on the upper surface of the cell element isolation film 105.

A bottom surface of the node contact pad 125 may be disposed on the upper surface of the cell element isolation film 105. The bottom surface of the node contact pad 125 may contact the upper surface of the cell element isolation film 105. For example, an entirety of the node contact pad 125 may be disposed on the upper surface of the substrate 100. In this regard, the node contact pad 125 may correspond to the node pad XP.

Based on the upper surface of the cell element isolation film 105, a vertical level of the upper surface 125US of the node contact pad may be lower than that of the upper surface 146US of the bit-line contact. Based on the upper surface of the cell element isolation film 105, a vertical level of the upper surface 125US of the node contact pad may be lower than that of a bottom surface of the cell conductive line 140.

A contact isolation structure 145ST may space node contact pads 125 adjacent to each other in the first direction DR1 from each other. Although not shown, the contact isolation structure 145ST may space node contact pads 125 adjacent to each other in the second direction DR2 from each other. The contact isolation structure 145ST covers the upper surface 125US of the node contact pad.

The contact isolation structure 145ST may include a contact isolation pattern 145 and an upper cell insulating film 135. The upper cell insulating film 135 may be disposed on the contact isolation pattern 145.

When the node contact pad 125 includes a first node contact pad and a second node contact pad spaced apart from each other in the first direction DR1, the contact isolation pattern 145 may isolate the first node contact pad and the second node contact pad from each other in the first direction DR1. Although not shown, the contact isolation pattern 145 may isolate node contact pads 125 adjacent to each other in the second direction DR2 from each other.

An entirety of the upper surface 125US of the node contact pad may not be in contact with an entirety of the storage pad 160. In other words, a width of an interface between the node contact pad 121 and the storage pad 160 in the first direction DR1 may be smaller than a width of the upper surface 125US of the node contact pad in the first direction DR1.

The bit-line spacer 150 may be disposed on the upper surface 125US of the node contact pad.

The upper cell insulating film 135 covers the upper surface 125US of the node contact pad. When the node contact pad 125 includes the first node contact pad and the second node contact pad spaced apart from each other in the first direction DR1, the upper cell insulating film 135 may cover an upper surface of the first node contact pad and the upper surface of the second node contact pad.

An upper surface 135US of the upper cell insulating film may be coplanar with the upper surface 146US of the bit-line contact. That is, based on the upper surface of the cell element isolation film 105, a vertical level of the upper surface 135US of the upper cell insulating film may be equal to a vertical level of the upper surface 146US of the bit-line contact.

The cell conductive line 140 may be disposed on the upper surface of the contact isolation structure 145ST. The cell conductive line 140 may be disposed on the upper surface 135US of the upper cell insulating film. An upper surface of the contact isolation structure 145ST may be the upper surface 135US of the upper cell insulating film. The upper surface of the contact isolation structure 145ST may be coplanar with the bottom surface of the cell conductive line 140.

For example, the contact isolation pattern 145 may include at least one of silicon nitride SiN, silicon oxynitride (SiON), silicon oxide SiO2, silicon carbonitride (SiCN), silicon oxycarbonitride (SiOCN), and combinations thereof. The upper cell insulating film 135 may be a single film. However, as shown, the upper cell insulating film 135 may be embodied as a stack of films including a first upper cell insulating film 136 and a second upper cell insulating film 137. For example, the first upper cell insulating film 136 may include a silicon oxide film, and the second upper cell insulating film 137 may include a silicon nitride film. The present disclosure is not limited thereto. It is shown that a width of the upper cell insulating film 135 in the first direction DR1 decreases as the upper cell insulating film 135 extends away from the substrate 100. The present disclosure is not limited thereto.

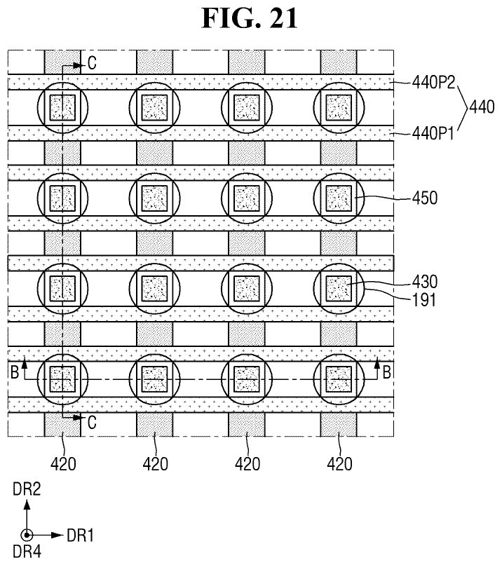

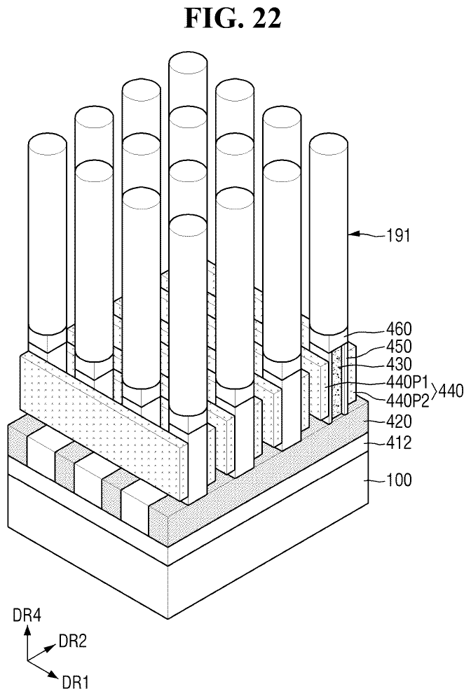

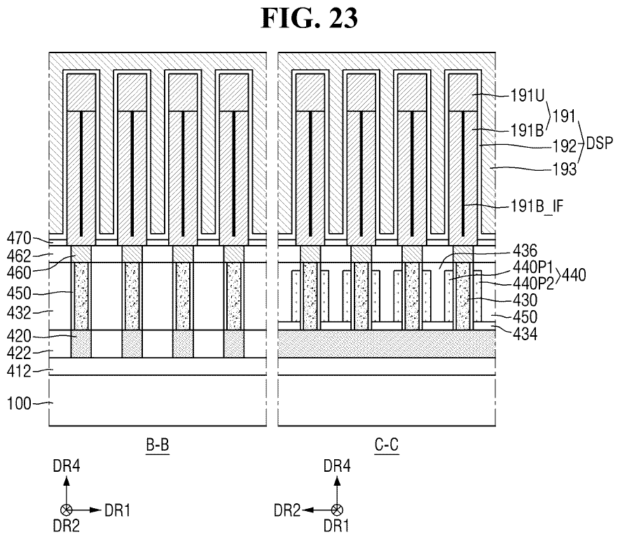

FIG. 21 is a layout diagram for illustrating a semiconductor memory device according to some implementations. FIG. 22 is a perspective view for illustrating a semiconductor memory device according to some implementations. FIG. 23 is a cross-sectional view cut along lines B-B and C-C of FIG. 21.

For convenience of illustration, FIG. 23 excludes the first and second lower electrode supports 50 and 55, and the first upper electrode support 60.

Referring to FIGS. 21 to 23, the semiconductor memory device according to some implementations may include the substrate 100, a plurality of first conductive lines 420, a channel layer 430, a gate electrode 440, a gate insulating film 450, and the data storage pattern DSP.

The semiconductor memory device according to some implementations may be a memory device including a vertical channel transistor (VCT). The vertical channel transistor may refer to a structure in which a channel length of the channel layer 430 extends from the substrate 100 along a vertical direction.

A lower insulating layer 412 may be disposed on the substrate 100. The plurality of first conductive lines 420 may be disposed on the lower insulating layer 412 and may be spaced apart from each other in the first direction DR1 and extend in the second direction DR2. A plurality of first insulating patterns 422 may be disposed on the lower insulating layer 412 so as to fill a space between adjacent ones of the plurality of first conductive lines 420. The plurality of first insulating patterns 422 may extend in the second direction DR2. An upper surface of the plurality of first insulating patterns 422 may be positioned at the same vertical level as that of an upper surface of the plurality of first conductive lines 420. Each of the plurality of first conductive lines 420 may function as a bit-line.

Each of the plurality of first conductive lines 420 may include at least one of a semiconductor material doped with impurities, a metal, a conductive metal nitride, a conductive metal silicide, a conductive metal oxide, or a combination thereof. For example, each of the plurality of first conductive lines 420 may include at least one of polysilicon doped with impurities, Al, Cu, Ti, Ta, Ru, W, Mo, Pt, Ni, Co, TiN, TaN, WN, NbN, TiAl, TiAlN, TiSi, TiSiN, TaSi, TaSiN, RuTiN, NiSi, CoSi, IrOx, RuOx, or a combination thereof, but may not be limited thereto. Each of the plurality of first conductive lines 420 may include a single layer or multiple layers made of the aforementioned materials. In some implementations, each of the plurality of first conductive lines 420 may include graphene, carbon nanotubes, or a combination thereof.

The channel layer 430 may have a matrix form in which channels are spaced apart from each other in each of the first direction DR1 and the second direction DR2 and are disposed on the plurality of first conductive lines 420, respectively. Each channel of the channel layer 430 may have a first width according to the first direction DR1 and a first vertical dimension according to the fourth direction DR4, wherein the first vertical dimension may be greater than the first width. In this regard, the fourth direction DR4 may intersect the first direction DR1 and the second direction DR2, and may be, for example, a direction perpendicular to the upper surface of the substrate 100. For example, the first vertical dimension may be about 2 to 10 times that of the first width. However, the disclosure is not limited thereto. A bottom portion of each channel of the channel layer 430 may function as a third source/drain area (not shown), while a top portion of each channel of the channel layer 430 may function as a fourth source/drain area (not shown). A portion of each channel of the channel layer 430 between the third and fourth source/drain areas may function as a channel area (not shown).

In one example, the channel layer 430 may include an oxide semiconductor. For example, the oxide semiconductor may include InₓGa_{y}Zn_{z}O, InₓGa_{y}Si_{z}O, InₓSn_{y}Zn_{z}O, InₓZn_{y}O, ZnₓO, ZnₓSn_{y}O, ZnₓO_{y}N, ZrₓZn_{y}Sn_{z}O, SnₓO, HfₓIn_{y}Zn_{z}O, GaₓZn_{y}Sn_{z}O, AlₓZn_{y}Sn_{z}O, YbₓGa_{y}Zn_{z}O, InₓGa_{y}O or combinations thereof. The channel layer 430 may include a single layer or multiple layers made of the oxide semiconductor. In some examples, the channel layer 430 may have a bandgap energy greater than that of silicon. For example, the channel layer 430 may have a bandgap energy of about 1.5 eV to about 5.6 eV. For example, the channel layer 430 may have optimal channel performance when the channel layer 430 has a bandgap energy of about 2.0 eV to 4.0 eV. For example, the channel layer 430 may be made of a polycrystalline material or an amorphous material (e.g., amorphous silicon), but may not be limited thereto. In another example, the channel layer 430 may include graphene, carbon nanotubes, or a combination thereof. In still another example, the channel layer 430 may include a silicon-based semiconductor material. The channel layer 430 may include a single crystal semiconductor material. For example, the channel layer 430 may include single crystal silicon or single crystal silicon-germanium. The present disclosure is not limited thereto.

The gate electrode 440 may extend in the first direction DR1 and may be formed on both side walls of each channel of the channel layer 430. The gate electrode 440 may include a first sub-gate electrode 440P1 facing toward a first side wall of the channel layer 430, and a second sub-gate electrode 440P2 facing toward a second side wall opposite to the first side wall of the channel layer 430. As one channel of the channel layer 430 is disposed between the first sub-gate electrode 440P1 and the second sub-gate electrode 440P2, the semiconductor device may have a dual gate transistor structure. However, the present disclosure is not limited thereto. The second sub-gate electrode 440P2 may be omitted and thus only the first sub-gate electrode 440P1 facing toward the first side wall of the channel layer 430 may be formed, so that a single gate transistor structure may be implemented.

The gate electrode 440 may include at least one of metal, conductive metal nitride, conductive metal carbonitride, conductive metal carbide, metal silicide, doped semiconductor material, conductive metal oxynitride, and conductive metal oxide. The gate electrode 440 may include, for example, at least one of TiN, TaC, TaN, TiSiN, TaSiN, TaTiN, TiAlN, TaAlN, WN, Ru, TiAl, TiAlC-N, TiAlC, TiC, TaCN, W, Al, Cu, Co, Ti, Ta, Ni, Pt, Ni-Pt, Nb, NbN, NbC, Mo, MoN, MoC, WC, Rh, Pd, Ir, Ag, Au, Zn, V, RuTiN, TiSi, TaSi, NiSi, CoSi, IrOₓ, RuOₓ and combinations thereof. The present disclosure is not limited thereto.

The gate insulating film 450 surrounds a side wall of each channel of the channel layer 430 and may be interposed between each channel of the channel layer 430 and the gate electrode 440. For example, as shown in FIG. 21, an entirety of a side wall of each channel of the channel layer 430 may be surrounded with the gate insulating film 450, and a portion of a side wall of the gate electrode 440 may contact the gate insulating film 450. In other implementations, the gate insulating film 450 may extend in an extension direction of the gate electrode 440, that is, the first direction DR1, and only two side walls facing toward the gate electrode 440 among all of side walls of each channel of the channel layer 430 may contact the gate insulating film 450.

For example, the gate insulating film 450 may include at least one of silicon oxide, silicon nitride, silicon oxynitride, or a high dielectric constant material having a higher dielectric constant than that of silicon oxide. The high dielectric constant material may include, for example, at least one of boron nitride, hafnium oxide, hafnium silicon oxide, hafnium aluminum oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, lead zinc niobate, or combinations thereof. However, implementations of the present disclosure are not limited thereto.

A plurality of second insulating patterns 432 may extend along the second direction DR2 and may be disposed on the plurality of first insulating patterns 422, respectively. Each channel of the channel layer 430 may be disposed between two adjacent second insulating patterns 432 of the plurality of second insulating patterns 432. Further, a first buried layer 434 and a second buried layer 436 may be disposed between two adjacent second insulating patterns 432 and in a space between two adjacent channels of the channel layer 430. The first buried layer 434 may occupy a bottom portion of a space between two adjacent channels of the channel layer 430. The second buried layer 436 may be formed to fill a remainder of the space between the two adjacent channels of the channel layer 430 and may be disposed on the first buried layer 434. An upper surface of the second buried layer 436 may be coplanar with an upper surface of the channel layer 430, and the second buried layer 436 may cover an upper surface of the gate electrode 440. Alternatively, each of the plurality of second insulating patterns 432 and each of the plurality of first insulating patterns 422 may constitute a continuous material layer and thus may be monolithic. Alternatively, the second buried layer 436 and the first buried layer 434 may constitute a continuous material layer and thus may be monolithic.

Each capacitor contact 460 may be disposed on each channel of the channel layer 430. Each capacitor contact 460 may vertically overlap each channel of the channel layer 430. Thus, the capacitor contacts 460 may be arranged in a matrix form in which the capacitor contacts 460 are spaced apart from each other in each of the first direction DR1 and the second direction DR2. The capacitor contact 460 may include at least one of polysilicon doped with impurities, Al, Cu, Ti, Ta, Ru, W, Mo, Pt, Ni, Co, TiN, TaN, WN, NbN, TiAl, TiAlN, TiSi, TiSiN, TaSi, TaSiN, RuTiN, NiSi, CoSi, IrOₓ, RuOₓ, or a combination thereof, but may not be limited thereto. An upper insulating layer 462 may surround a side wall of each capacitor contact 460 and may be disposed on the plurality of second insulating patterns 432 and the second buried layer 436.

A third etch stop film 470 may be disposed on the upper insulating layer 462. The data storage pattern DSP may be disposed on the third etch stop film 470. The data storage pattern DSP may include the lower electrode 191, the capacitor dielectric film 192, and the upper electrode 193. The lower electrode 191 may extend through the third etch stop film 470 and be electrically connected to the upper surface of the capacitor contact 460.

In illustrative implementations, the lower electrode 191 may vertically overlap the capacitor contact 460. The lower electrodes 191 may be arranged in a matrix form in which the lower electrodes 191 are spaced apart from each other in each of the first direction DR1 and the second direction DR2. Alternatively, a landing pad (not shown) may be further disposed between the capacitor contact 460 and the lower electrode 191, and thus, the lower electrodes 191 may be arranged in a hexagonal shape.

The descriptions of the lower electrode 191, the capacitor dielectric film 192, and the upper electrode 193 may be substantially the same as those as set forth above using FIGS. 1 to 15 and, thus, are omitted below.

Although, in FIG. 23, the first and second lower electrode supports 50 and 55, and the first upper electrode support 60 are not shown, the descriptions about the first and second lower electrode supports 50 and 55, and the first upper electrode support 60 may be substantially the same as those set forth above using FIGS. 1 to 15.

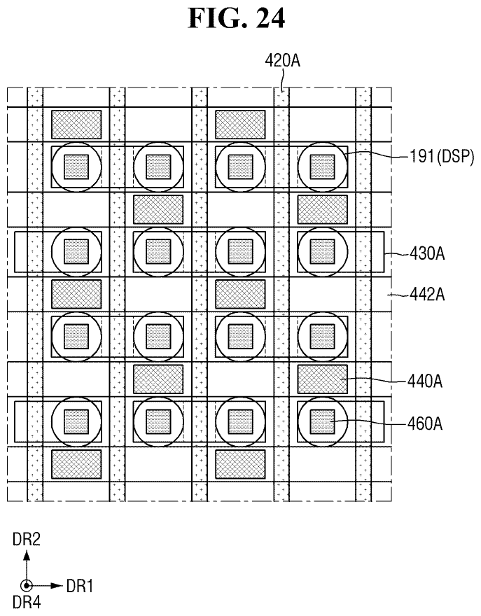

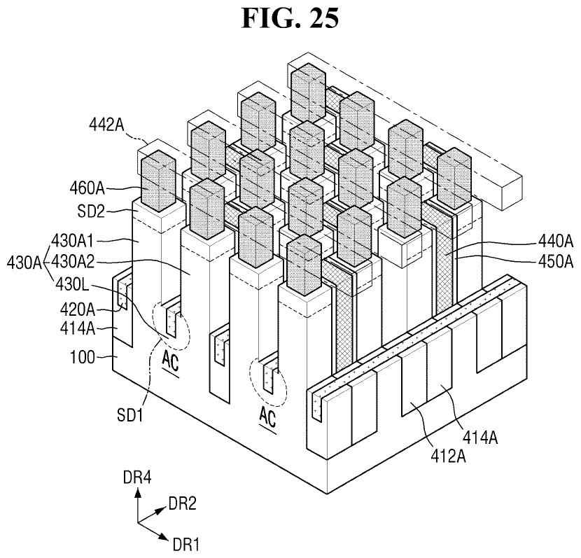

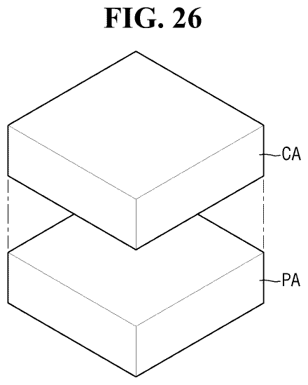

FIG. 24 is a layout diagram for illustrating a semiconductor memory device according to some implementations. FIG. 25 is a perspective view for illustrating a semiconductor memory device according to some implementations. FIG. 26 is a diagram for illustrating a semiconductor memory device according to some implementations.

Referring to FIG. 24 and FIG. 25, the semiconductor memory device according to some implementations may include the substrate 100, a plurality of first conductive lines 420A, a channel structure 430A, a contact gate electrode 440A, a plurality of second conductive lines 442A, and the data storage pattern DSP. The semiconductor memory device according to some implementations may be a memory device including a vertical channel transistor (VCT).

A plurality of active areas AC may be defined in the substrate 100 by a first element isolation pattern 412A and a second element isolation pattern 414A. The channel structure 430A may be disposed in each of the active areas AC. The channel structure 430A may include a first active pillar 430A1 and a second active pillar 430A2 extending in a vertical direction, and a connector 430L connected to a bottom portion of the first active pillar 430A1 and a bottom portion of the second active pillar 430A2. A first source/drain area SD1 may be disposed in the connector 430L. A second source/drain area SD2 may be disposed in a top portion of each of the first and second active pillars 430A1 and 430A2. Each of the first active pillar 430A1 and the second active pillar 430A2 may constitute an independent unit memory cell.

The plurality of first conductive lines 420A may extend in a direction intersecting the plurality of active areas AC. For example, the plurality of first conductive lines 420A may extend in the second direction DR2. One of the plurality of first conductive lines 420A may be disposed on the connector 430L and between the first active pillar 430A1 and the second active pillar 430A2. One first conductive line 420A may be disposed on the first source/drain area SD1. Another first conductive line 420A adjacent to said one first conductive line 420A may be disposed between two channel structures 430A. One first conductive line 420A of the plurality of first conductive lines 420A may function as a common bit-line commonly included in two unit memory cells respectively corresponding to the first active pillar 430A1 and the second active pillar 430A2 respectively disposed on both sides of said one first conductive line 420A.

One contact gate electrode 440A may be disposed between two channel structures 430A adjacent to each other in the second direction DR2. For example, the contact gate electrode 440A may be disposed between the first active pillar 430A1 included in one channel structure 430A and the second active pillar 430A2 of the channel structure 430A adjacent thereto. One contact gate electrode 440A may be shared by the first active pillar 430A1 and the second active pillar 430A2 respectively disposed on both side walls thereof. The gate insulating film 450A may be disposed between the contact gate electrode 440A and the first active pillar 430A1 and between the contact gate electrode 440A and the second active pillar 430A2. The plurality of second conductive lines 442A may extend in the first direction DR1. Each one of the plurality of second conductive lines 442A may be disposed on an upper surface of each contact gate electrode 440A. Each of the plurality of second conductive lines 442A may function as a word-line of the semiconductor memory device.

A capacitor contact 460A may be disposed on the channel structure 430A. the capacitor contact 460A may be disposed on the second source/drain area SD2. The data storage pattern DSP may be disposed on the capacitor contact 460A.

Referring to FIG. 26, the semiconductor memory device according to some implementations may have a COP (Cell on Peri) structure in which a cell array area CA is disposed on a peripheral structure area PA.

The cell array area CA may include the vertical channel transistor VCT in FIGS. 21 to 25. In the peripheral structure area PA, a sensing transistor, a transfer transistor, a driving transistor, etc. connected to the vertical channel transistor of FIGS. 21 to 25 may be disposed.

FIGS. 27 to 31 are diagrams of intermediate structures corresponding to intermediate steps of a semiconductor memory device manufacturing method according to some implementations. For convenience, contents duplicate with those as described using FIGS. 1 to 11 are briefly described or the descriptions thereof are omitted.

Referring to FIG. 27, the interlayer insulating film 20 may be formed on the substrate 100.

The conductive pattern 30 may be formed within the interlayer insulating film 20. The first etch stop film 25 may be formed on the conductive pattern 30 and the interlayer insulating film.

A first mold insulating film 31, a first lower electrode support film 50L, a second mold insulating film 32, and a second lower electrode support film 55L may be sequentially formed on the first etch stop film 25.

Each of the first mold insulating film 31 and the second mold insulating film 32 may include at least one of silicon oxide, silicon nitride, silicon oxynitride, and a low-k material with a dielectric constant lower than that of silicon oxide. The present disclosure is not limited thereto.

Each of the first lower electrode support film 50L and the second lower electrode support film 55L may include at least one of silicon nitride, silicon carbonitride, silicon boronitride, silicon carbonate, silicon oxynitride, and silicon oxycarbonitride. The present disclosure is not limited thereto.

A lower electrode hole 191H may be formed within the first and second lower electrode support films 50L and 55L and the first and second mold insulating films 31 and 32.

The lower electrode hole 191H may extend through the first etch stop film 25. The lower electrode hole 191H may expose the conductive pattern 30.

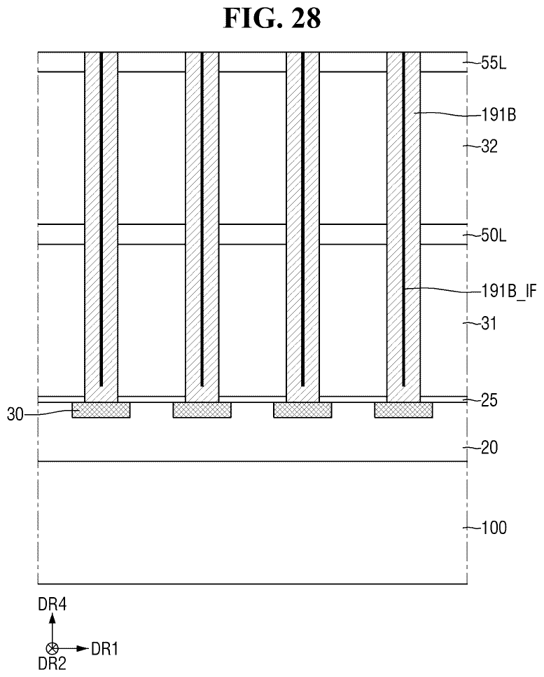

Referring to FIG. 27 and FIG. 28, the lower pattern 191B of the lower electrode may be formed on the conductive pattern 30.

The lower pattern 191B of the lower electrode may be formed within the lower electrode hole 191H. The lower pattern 191B of the lower electrode fills the lower electrode hole 191H. While the lower pattern 191B of the lower electrode is formed, the lower inner interface 191B_IF may be formed within the lower pattern 191B of the lower electrode.

The lower pattern 191B of the lower electrode may be formed using, for example, atomic layer deposition (ALD). The present disclosure is not limited thereto. The lower pattern 191B of the lower electrode may be formed along a sidewall and a bottom surface of the lower electrode hole 191H, and then may finally fill an entirety of the lower electrode hole 191H. While the lower pattern 191B of the lower electrode is formed, a thickness of each of both lower patterns 191B of the lower electrode respectively formed on both opposing sidewalls of the lower electrode hole 191H increases such that both lower patterns 191B of the lower electrode meet each other. In a cross-sectional view, the lower patterns 191B of the lower electrode are respectively formed on opposing sidewalls of the lower electrode hole 191H. Where the lower patterns 191B meet each other the lower inner interface 191B_IF is formed.

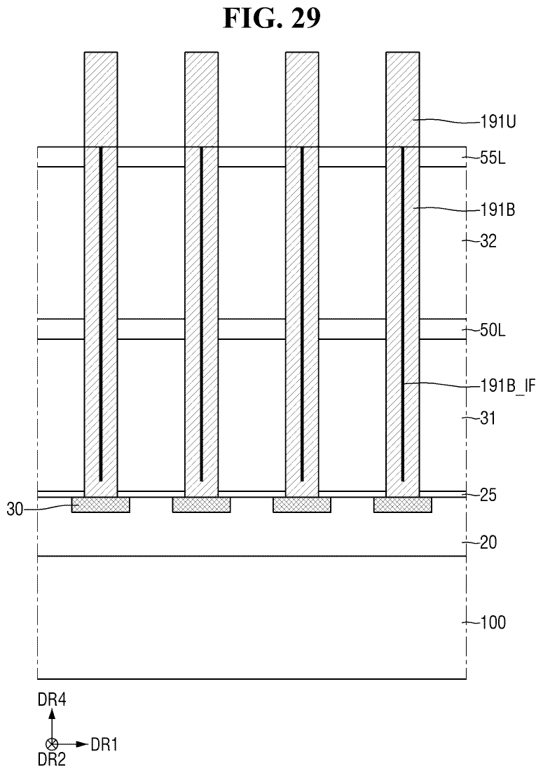

Referring to FIG. 29, the upper pattern 191U of the lower electrode may be formed on the lower pattern 191B of the lower electrode.

The upper pattern 191U of the lower electrode may protrude in the fourth direction DR4 beyond the second lower electrode support film 55L.

The upper pattern 191U of the lower electrode may be formed using a selective growth method. The selective growth method may be, for example, a method of selectively depositing a conductive material on a conductive material.

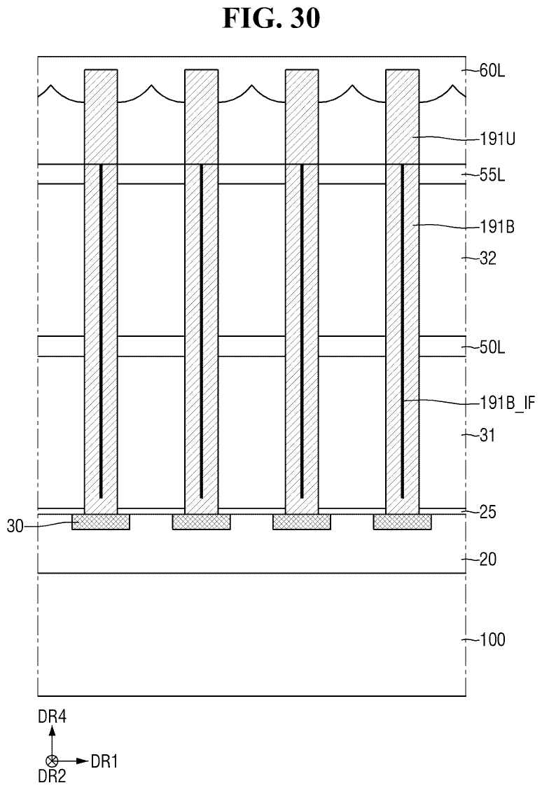

Referring to FIG. 30, a first upper electrode support film 60L may be formed on the upper pattern 191U of the lower electrode.

The first upper electrode support film 60L may contact a portion of the sidewall of the upper pattern 191U of the lower electrode. In the semiconductor memory device manufacturing method according to some implementations, the first upper electrode support film 60L may contact the upper surface of the upper pattern 191U of the lower electrode.

In one example, the first upper electrode support film 60L may be formed using a deposition method with poor step coverage. Between the upper patterns 191U of adjacent lower electrodes, a bottom surface of the first upper electrode support film 60L facing the second lower electrode support film 55L may include a plurality of inclined surfaces. Between the first upper electrode support film 60L and the second lower electrode support film 55L, there may be a space not filled with an insulating material. The present disclosure is not limited thereto.

In another example, the first upper electrode support film 60L may be formed using a deposition method with good step coverage. In this case, unlike what is shown, the first upper electrode support film 60L may be formed in the same shape as that of the first upper electrode support 60 as described using FIGS. 7 to 9. Before the first upper electrode support film 60L is formed, a sacrificial mold insulating film may be formed on the second lower electrode support film 55L. The sacrificial mold insulating film may cover a portion of the sidewall of the upper pattern 191U of the lower electrode.

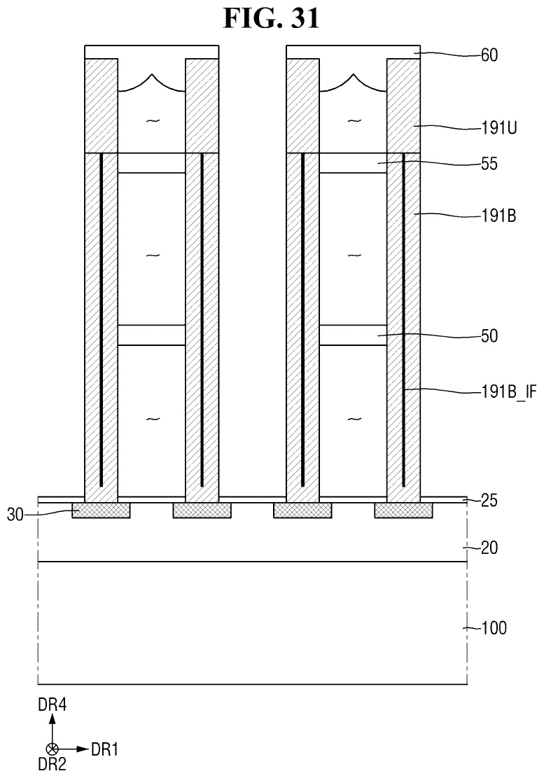

Referring to FIG. 30 and FIG. 31, the first upper electrode support 60 may be formed by patterning the first upper electrode support film 60L.

If the sacrificial mold insulating film is formed on the second lower electrode support film 55L, the sacrificial mold insulating film may be removed.

Subsequently, the second lower electrode support film 55L may be patterned to form the second lower electrode support 55. As the second lower electrode support 55 is formed, the second mold insulating film 32 may be exposed.

Using wet etching, the second mold insulating film 32 may be removed. The second mold insulating film 32 may be removed, thereby exposing the first lower electrode support film 50L.

Subsequently, the first lower electrode support film 50L may be patterned to form the first lower electrode support 50. Thus, the first mold insulating film 31 may be exposed. Subsequently, using wet etching, the first mold insulating film 31 may be removed.

Subsequently, referring to FIG. 1, the capacitor dielectric film 192 and the upper electrode 193 may be formed.

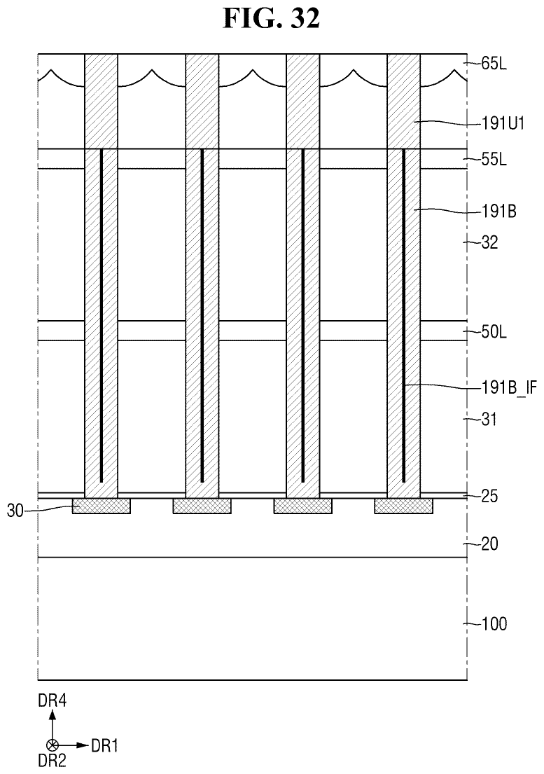

FIGS. 32 to 35 are diagrams of intermediate structures corresponding to intermediate step of a semiconductor memory device manufacturing method according to some implementations. For convenience, contents duplicate with those as described using FIGS. 14 to 15 are briefly described or the descriptions thereof are omitted.

For reference, FIG. 32 may be a manufacturing process that occurs after FIG. 28.

Referring to FIG. 32, the first sub-upper pattern 191U1 may be formed on the lower pattern 191B of the lower electrode.

The first sub-upper pattern 191U1 may protrude in the fourth direction DR4 beyond the second lower electrode support film 55L. The first sub-upper pattern 191U1 may be formed using, for example, a selective growth method.

Subsequently, a second upper electrode support film 65L may be formed on the second lower electrode support film 55L.

The second upper electrode support film 65L may contact the sidewall of the first sub-upper pattern 191U1. The second upper electrode support film 65L may cover a portion of the sidewall of the first sub-upper pattern 191U1.

For example, between the second upper electrode support film 65L and the second lower electrode support film 55L, there may be a space that is not filled with an insulating material.

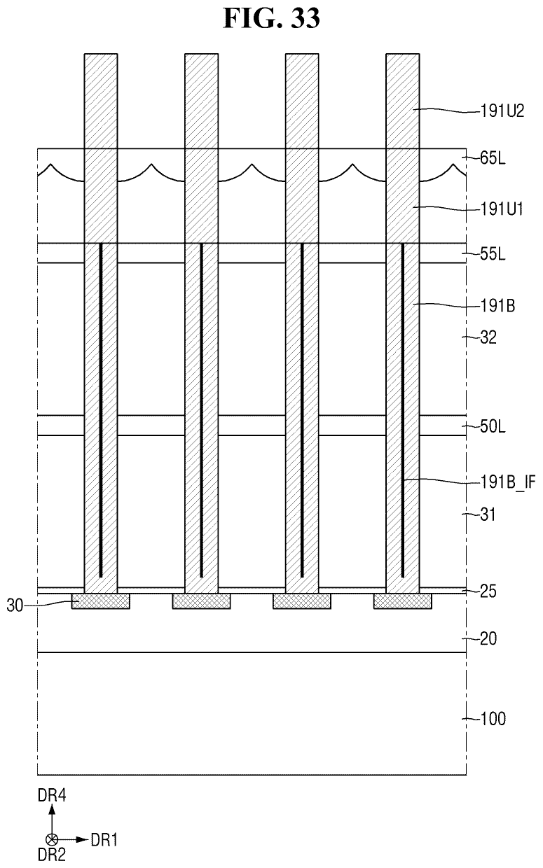

Referring to FIG. 33, the second sub-upper pattern 191U2 may be formed on the first sub-upper pattern 191U1.

The second sub-upper pattern 191U2 may protrude in the fourth direction DR4 beyond the second upper electrode support film 65L. The second sub-upper pattern 191U2 may be formed using, for example, a selective growth method.

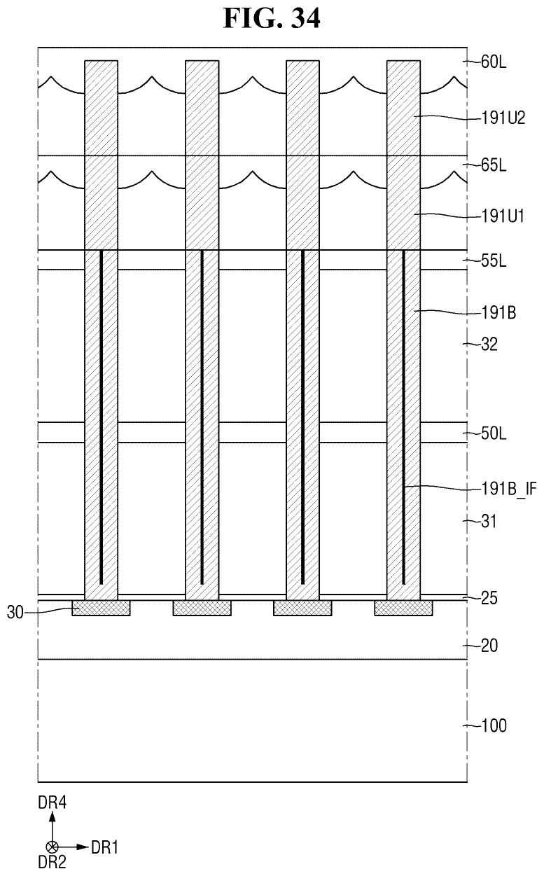

Referring to FIG. 34, the first upper electrode support film 60L may be formed on the second sub-upper pattern 191U2.

The first upper electrode support film 60L may be in contact with a portion of the sidewall of the second sub-upper pattern 191U2. In the semiconductor memory device manufacturing method according to some implementations, the first upper electrode support film 60L may contact the upper surface of the second sub-upper pattern 191U2.

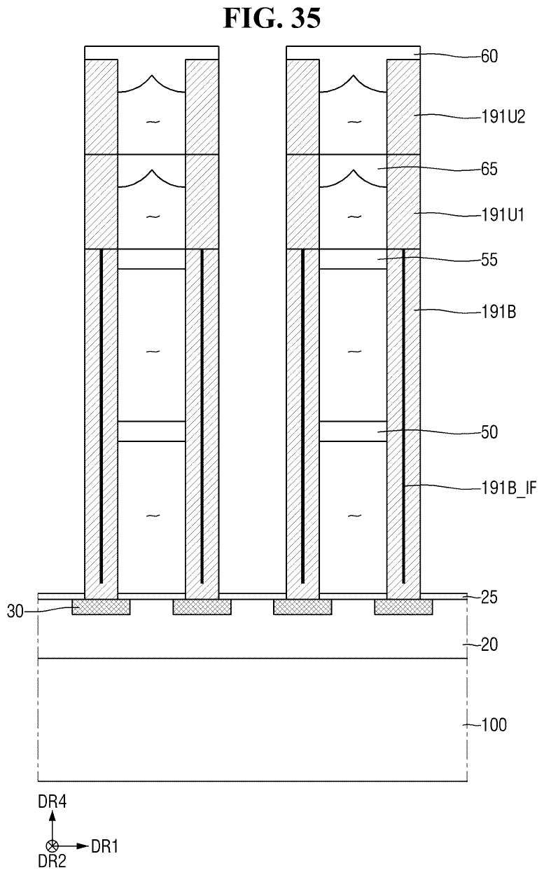

Referring to FIG. 34 and FIG. 35, the first upper electrode support film 60L, the second upper electrode support film 65L, the second lower electrode support film 55L, and the first lower electrode support film 50L may be patterned such that the first upper electrode support 60, the second upper electrode support 65, the second lower electrode support 55, and the first lower electrode support 50 may be formed.

In a process of forming the first upper electrode support 60, the second upper electrode support 65, the second lower electrode support 55 and the first lower electrode support 50, the first mold insulating film 31 and the second mold insulating film 32 may be removed using wet etching.

Unlike what is shown in FIGS. 32 to 35, a sacrificial electrode support film may be formed instead of the second upper electrode support film 65L. The sacrificial electrode support film may be removed in a process that removes the second mold insulating film 32. In this case, the second upper electrode support 65 may not be formed near a border of the first sub-upper pattern 191U1 and the second sub-upper pattern 191U2, as shown in FIG. 12 and FIG. 13.

Although implementations of the present disclosure have been described with reference to the accompanying drawings, implementations of the present disclosure are not limited to the above implementations, but may be implemented in various different forms. A person skilled in the art may appreciate that the present disclosure may be practiced in other concrete forms without changing the technical spirit or essential characteristics of the present disclosure. Therefore, it should be appreciated that the implementations as described above is not restrictive but illustrative in all respects.

While this disclosure contains many specific implementation details, these should not be construed as limitations on the scope of what may be claimed. Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

In concluding the detailed description, those skilled in the art will appreciate that many variations and modifications may be made to the preferred implementations without substantially departing from the principles of the present disclosure. Therefore, the disclosed preferred implementations of the invention are used in a generic and descriptive sense only and not for purposes of limitation.

What is claimed is:

1. A semiconductor memory device comprising:
a conductive pattern disposed on a substrate;
a lower electrode connected to the conductive pattern, and extending in a first direction, wherein the lower electrode includes a lower pattern and an upper pattern, wherein the lower pattern is disposed between the upper pattern and the conductive pattern;
a capacitor dielectric film disposed on the lower electrode; and
an upper electrode disposed on the capacitor dielectric film,
wherein the lower pattern includes a lower inner interface extending in the first direction,
wherein the upper pattern is free of an inner interface extending in the first direction.

2. The semiconductor memory device of claim 1, wherein the lower inner interface extends to a bottom surface of the upper pattern.

3. The semiconductor memory device of claim 1, wherein the upper pattern includes a plurality of sub-upper patterns disposed on the lower pattern and stacked in the first direction.

4. The semiconductor memory device of claim 1, wherein the lower pattern and the upper pattern include a same material.

5. The semiconductor memory device of claim 1, further comprising a first upper electrode support in contact with an upper surface of the upper pattern and a sidewall of the upper pattern,
wherein the first upper electrode support includes a plate portion and a protrusion,
wherein the plate portion of the first upper electrode support is in contact with the upper surface of the upper pattern,
wherein the protrusion of the first upper electrode support protrudes from the plate portion of the first upper electrode support, and contacts the sidewall of the upper pattern.

6. The semiconductor memory device of claim 5, wherein a thickness in the first direction of the protrusion of the first upper electrode support decreases and then increases as the protrusion extends away from a first sidewall of the upper pattern.

7. The semiconductor memory device of claim 5, further comprising a second upper electrode support disposed between the first upper electrode support and the conductive pattern, wherein the second upper electrode support is in contact with the sidewall of the upper pattern,
wherein a thickness in the first direction of the second upper electrode support decreases and then increases as the second upper electrode support extends away from a first sidewall of the upper pattern.

8. The semiconductor memory device of claim 7, wherein the second upper electrode support includes an upper surface and a bottom surface opposite to each other in the first direction,
wherein the upper surface of the second upper electrode support is flat,
wherein the bottom surface of the second upper electrode support faces the conductive pattern and includes a plurality of inclined surfaces.

9. The semiconductor memory device of claim 1, further comprising a lower electrode support supporting the lower electrode, wherein the lower electrode support is in contact with a sidewall of the lower pattern,
wherein the lower electrode support includes an upper surface and a bottom surface opposite to each other in the first direction,
wherein the bottom surface of the lower electrode support faces the conductive pattern and is flat.

10. The semiconductor memory device of claim 1, wherein a width in a second direction of an upper surface of the lower pattern is equal to a width in the second direction of the upper pattern.

11. The semiconductor memory device of claim 1, wherein a width in a second direction of an upper surface of the lower pattern is smaller than a width in the second direction of the upper pattern.

12. A semiconductor memory device comprising:
a conductive pattern disposed on a substrate;
a lower electrode connected to the conductive pattern, and extending in a first direction, wherein the lower electrode includes a lower pattern and an upper pattern, wherein the lower pattern is disposed between the upper pattern and the conductive pattern;
a lower electrode support supporting the lower electrode and in contact with a sidewall of the lower pattern;
a capacitor dielectric film disposed on the lower electrode and the lower electrode support; and
an upper electrode disposed on the capacitor dielectric film,
wherein the lower electrode support includes an upper surface and a bottom surface opposite to each other in the first direction,
wherein the bottom surface of the lower electrode support faces the conductive pattern,
wherein the upper pattern protrudes in the first direction beyond the upper surface of the lower electrode support,
wherein at a boundary of the lower pattern and the upper pattern, a first crystal direction of the lower pattern is different from a second crystal direction of the upper pattern.

13. The semiconductor memory device of claim 12, wherein the first crystal direction is a second direction orthogonal to the first direction,
wherein the second crystal direction is the first direction.

14. The semiconductor memory device of claim 12, wherein each of the lower pattern and the upper pattern includes titanium nitride.

15. The semiconductor memory device of claim 12, wherein the upper pattern includes a plurality of sub-upper patterns disposed on the lower pattern and stacked in the first direction.

16. The semiconductor memory device of claim 12, further comprising a first upper electrode support in contact with an upper surface of the upper pattern and a sidewall of the upper pattern,
wherein the first upper electrode support includes a plate portion and a protrusion,
wherein the plate portion of the first upper electrode support is in contact with the upper surface of the upper pattern,
wherein the protrusion of the first upper electrode support protrudes from the plate portion of the first upper electrode support, and contacts the sidewall of the upper pattern.

17. The semiconductor memory device of claim 16, wherein the first upper electrode support includes an upper surface and a bottom surface opposite to each other in the first direction,
wherein the upper surface of the first upper electrode support is flat,
wherein the bottom surface of the first upper electrode support faces the lower electrode support and includes a plurality of inclined surfaces.

18. The semiconductor memory device of claim 16, wherein a bottom surface of the lower electrode support is flat.

19. A semiconductor memory device comprising:
a substrate including an active area defined by an element isolation film and extending in a first direction, wherein the active area includes a first portion and a second portion defined on each of both opposing sides of the first portion;
a word-line disposed within the substrate and the element isolation film, and extending in a second direction different from the first direction, wherein the word-line extends across an area between the first portion of the active area and the second portion of the active area;
a bit-line contact connected to the first portion of the active area;
a bit-line disposed on the bit-line contact and connected to the bit-line contact, wherein the bit-line extends in a third direction different from the first direction and the second direction;
a landing pad connected to the second portion of the active area; and
a capacitor,
wherein the capacitor includes:
a lower electrode connected to the landing pad and extending in the third direction;
a capacitor dielectric film disposed on the lower electrode; and
an upper electrode disposed on the capacitor dielectric film,
wherein the lower electrode includes a lower pattern connected to the landing pad and an upper pattern disposed on the lower pattern,
wherein the lower pattern includes a lower inner interface extending in the third direction
wherein the upper pattern is free of an inner interface extending in the third direction.

20. The semiconductor memory device of claim 19, wherein the upper pattern includes a plurality of sub-upper patterns disposed on the lower pattern and stacked in the third direction.
